(19) United States
(12) Patent Application Publication
(10) Pub. No.: US 2026/0118583 A1
(43) Pub. Date: Apr. 30, 2026

(54) PHOTONIC WAFER-SCALE INTERPOSER WITH TAPERED WAVEGUIDES

(71) Applicant: Volantis Semiconductor, Inc., Portland, OR (US)

(72) Inventor: Tapabrata Ghosh, San Francisco, CA (US)

(73) Assignee: Volantis Semiconductor, Inc., Portland, OR (US)

(21) Appl. No.: 19/079,851

(22) Filed: Mar. 14, 2025

Related U.S. Application Data
(63) Continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. G02B 6/122; G02B 6/125

(52) U.S. Cl. CPC G02B 6/1228; G02B 6/125

(57) ABSTRACT

Techniques for sending data are disclosed. A photonic wafer-scale interposer (PWSI) is accessed. The PWSI includes a plurality of waveguides. A front side of the PWSI is bonded to at least two chiplets. The at least two chiplets are coupled. The coupling is based on one or more waveguides in the plurality of waveguides. Data is sent, by a first chiplet within the at least two chiplets, to a second chiplet within the at least two chiplets. The sending is based on a first waveguide within the one or more waveguides. A transition is made between at least one low confinement region and at least one high confinement region. The transitioning includes the first waveguide. The data that was sent is received by the second chiplet. Power is provided to the at least two chiplets based on a back side of the PWSI.

### RELATED APPLICATIONS

This application is a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive” Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025, is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Back Side Power Delivery For Wafer-Scale Integration With Solderless Modular Power Substrates” Ser. No. 19/023,647, filed Jan. 16, 2025 is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024 is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling” Ser. No. 63/714,353, filed Oct. 31, 2024.

Each of the foregoing applications is hereby incorporated by reference in its entirety.

### FIELD OF ART

This application relates generally to sending data and more particularly to a photonic wafer-scale interposer with tapered waveguides.

### BACKGROUND

The ability of humans to communicate with one another has evolved over millennia, where interhuman communication takes many forms. The forms of communication include nonverbal communication, written communication, and verbal communication. By some estimates, nonverbal communication first developed around 100,000 years ago, relying on body gestures and hand gestures, facial expressions, and non-word sounds. A body gesture such as a shoulder shrug, a hand gesture such as a pointing toward game, or a facial expression such as a smile could be used to indicate uncertainly, opportunity, and welcome, respectively. Pictorial communication developed comparably more recently, with estimates extending to roughly 30,000 years ago. Early examples of pictorial communications included cave paintings discovered in France and Spain. These drawings are thought to convey significant rituals, hunts, and other events important to early humans. Such pictorial representations eventually evolved in glyphs. Example systems of glyphs include hieroglyphs used by ancient Egyptians, cenotes used by the Mayans, and cuneiforms used by the Sumerians. The latter system was based on logographs and syllabograms, the former representing words or ideas, and the latter representing sounds. A further example of glyphs includes geoglyphs. These latter glyphs include large designs or motifs created on the ground. Examples of geoglyphs are found in Great Brittain and Peru. Written languages developed from the pictorial ones and were developed along with spoken languages. The formation of languages enabled humans to exchange more complicated concepts and to pass on traditions orally. The written forms of the languages enabled the recording of events and stories including culturally important history, lore, and traditions.

Interhuman communication continued to evolve. The invention of the printing press in China based on wooden moveable type, and its further enhancement by Gutenberg in the 15^{th} Century, based on metal type, enabled information to be captured, stored, and exchanged. Printed materials could be transported from place to place and shared with distant people. As the world became more mobile, devices were developed that enabled communication over great distances. The idea of sending information using electrical signals was proposed in the early 18^{th} century and eventually became Morse's telegraph of the 1830s. The telephone, a device for sending voice over great distances, was patented in 1867 by Bell. And Marconi is credited with inventing radio in 1902, enabling wireless communication.

In the late 20^{th} Century, digital communication enabled communication between humans located practically anywhere on Earth. Some digital communication is instantaneous, while others remain over time. Instantaneous digital communications include live chat, instant messaging, and video conferencing. This form of digital communication is “of the moment” and is typically not recorded. Non-instantaneous digital communication includes social media, websites, blogs, and podcasts. These digital communications can be revisited over time. And now, some forms of digital communication are driven by AI. This category includes chatbots that are designed to query humans using natural language in an attempt to assist them. Communication has evolved significantly over time.

### SUMMARY

The demand by computer users and other electronic device users for faster computers and devices, and improved applications, relentlessly drives new designs and architectures for devices and applications. Further, the users demand device features that enhance the usability of the devices. These device features now typically include biometric access, increased resolution cameras, and three-dimensional audio. These user requirements span the expansive range of computing devices. Whether the computers are vast server farms or handheld devices such as smartphones, users always desire systems and devices that are faster and more capable than the systems and devices currently in use. As a result, circuit designers continue to design and to fabricate improved integrated circuits that present ever-increasing processing performance, expanded data processing options, and “product differentiating” features. The differentiating features now include larger or folding touchscreens, higher resolution cameras with multiple lenses, spatial audio that simulates different listening environments, biometric sensing for facial and fingerprint recognition, and “entertainment” applications from games to personal emoji generators, among many other enhancements. However, increasing chip processing speeds and other capabilities such as AI processing force the addition of complex and large circuitry to the chips. To add new circuitry to the chips, designers employ two main design philosophies: increase the physical dimensions of the chip by making it larger or increase circuit density by reducing feature sizes. These techniques have so far been successful in meeting the never-ending customer demands for increased performance. As a result, microprocessors, graphics processors, machine learning accelerators, systems-on-chips (SoCs), and so on currently boast transistor counts into the tens of billions. Concomitant with increasing performance, the architectural improvements and added devices increase the power density of the chips, resulting in prodigious heat generation.

With the objective of increasing computational performance firmly in mind, many engineers and architects have directed their efforts toward wafer-scale integration. In an ideal world, a single chip would extend across an entire wafer (which can be called a monolithic wafer). Further, the feature sizes would include greatly reduced transistor sizes, minimum contact sizes, smaller wire widths and separation, and reductions of all other dimensions related to circuitry. In another example, the wafer can form an interposer with bonded chiplets. Regardless of methodology, to increase interconnection options, designers have considered through-silicon vias to provide direct connections between a front side of a chip (or wafer) and a back side of a chip. However, to reliably fabricate such interconnect, the wafers, for example, must be ground or polished to a thinness that supports the fabrication of the through-silicon vias. As a result, the thinned chips are prone to fracturing, not only because of the delicate nature of the composition of the wafer, but also because of the weights of the amassed elements bonded to, attached to, or otherwise connected to the wafers. Further, the coefficient of thermal expansion (CTE) can be different for various materials in a typical wafer stack-up, thus leading to failures after power is applied and non-uniform expansion occurs between elements. Finally, various connections to the wafer must be manufactured without damaging or rupturing other existing connections (for example, an oven typically used for a reflow process can damage chip connections such as controlled collapse chip connections (C4s)). Thus, proper support and stabilization of, power delivery to, connections to, and heat removal from the wafers have become paramount to prevent wafer damage or wafer failure.

Disclosed techniques enable a photonic wafer-scale interposer with tapered waveguides. A photonic wafer-scale interposer (PWSI) is accessed. The PWSI includes a plurality of waveguides. The waveguides can be within the PWSI. A front side of the PWSI is bonded to at least two chiplets. The chiplets can include AI accelerators, processors, switching chiplets, surface-emitting light sources, and so on. The front side of the PWSI can also be bonded to other elements that can include processor chips, accelerator chips, memory chips, and so on. The PWSI may include a plurality of through-silicon vias (TSVs). The at least two chiplets are coupled. The coupling is based on one or more waveguides in the plurality of waveguides. Data is sent, by a first chiplet within the at least two chiplets, to a second chiplet within the at least two chiplets. The sending can be based on a request by an external node for a data transfer. The sending is based on a first waveguide within the plurality of waveguides. The first waveguide can be within the PWSI. A transition is made between at least one low confinement region and at least one high confinement region. The transition includes the first waveguide. In a low confinement waveguide, a signal such as a light signal is not tightly confined within the core of the waveguide. In a high confinement waveguide, a light signal is tightly confined within the core of the waveguide. The second chiplet receives the data that was sent.

A method for sending data is disclosed comprising: accessing a photonic wafer-scale interposer (PWSI), wherein the PWSI includes a plurality of waveguides, and wherein a front side of the PWSI is bonded to at least two chiplets; coupling the at least two chiplets, wherein the coupling is based on one or more waveguides in the plurality of waveguides; sending data, by a first chiplet within the at least two chiplets, to a second chiplet within the at least two chiplets, wherein the sending is based on a first waveguide within the one or more waveguides; transitioning between at least one low confinement region and at least one high confinement region, wherein the transitioning includes the first waveguide; and receiving, by the second chiplet, the data that was sent.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for a photonic wafer-scale interposer with tapered waveguides.

FIG. 2 is a flow diagram for providing power.

FIG. 3 shows a wafer with multiple die.

FIG. 4 illustrates inter-die interconnect for wafer-scale integration.

FIG. 5 shows inter-die interconnect and redundancy for wafer-scale integration.

FIG. 6 illustrates a flip-chip and interposer with flip-chips for wafer-scale integration.

FIG. 7 is an example of a waveguide cross-section in Silicon-on-Insulator (SOI) technology.

FIG. 8 is a cross-section for a photonic wafer-scale interposer with chiplets.

FIG. 9 is an example of waveguide tapering.

FIG. 10 is an example of evanescent coupling.

FIG. 11 is a cross-section of an apparatus for a photonic wafer-scale interposer with tapered waveguides.

FIG. 12 is an example of a HyperX network topology implemented with a photonic wafer-scale integration (PWSI).

FIG. 13 is a system diagram for a photonic wafer-scale interposer with tapered waveguides.

### DETAILED DESCRIPTION

Techniques for sending data using a photonic wafer-scale interposer with tapered waveguides are disclosed. The development of new applications for processors, accelerators, and so on is driving demand for significant processing performance improvements. This demand places immense pressure on chip designers and chip architects to develop next generation chips that can provide processing power to computers, servers, cloud servers, large language model (LLM) engines, etc. To meet these demands, vastly increased numbers of transistors have been added to a wide variety of chips such as chiplets and systems-on-chip (SOCs). Chiplets can include processors, memories, switching elements, and so on. SOCs can include an immense range of circuitry which can include processors, memories, input/output (I/O) circuits, network switches, and other elements. The SOCs can be dimensionally large, possessing tens of billions of transistors. At the same time, the feature sizes of the transistors used for these large chips continue to shrink. According to Moore's law, the number of transistors that can fit into the same size chip should double every two years. While at some point, this doubling will likely end as the limits of lithography and physics are approached, in general, the “law” has held true for the last several decades. Keeping chip sizes roughly the same size while increasing transistor count is generally good news, but new technologies that drive smaller transistors also impose new challenges for designers. For example, as a transistor shrinks, leakage currents typically increase, resulting in higher power consumption for the chip. This effect, in combination with the active power required to operate billions of transistors, can drive extremely high-power densities for processors and other computing elements. Further, the wafers on which these large chips are fabricated are delicate. The wafers can fracture if the wafers are not properly handled and supported during fabrication, packing, deployment, etc.

The tremendous increase of interest in and use of artificial intelligence (AI) applications, such as large neural networks, AI transformers, and so on, can require hundreds or even thousands of processing elements. The AI applications can require that the processing elements handle, in some cases, trillions of computations. These processing elements can include chiplets, processor cores, multiprocessor cores, matrix computation accelerators, SOCs, ASICs, and so on. While multiple cores such as processor cores and memory cores can be included on the same chip, many chips, and thus, many processors, are required for executing these computationally intensive applications. The processing chips can be in communication with other processing chips that are located either locally or remotely. The processing chips are typically coupled via cards, data racks, and/or data centers. The chips, when taken together, introduce significant design challenges such as the provision of power to the chips, the cooling of all these chips, mounting of the chips, etc. For example, cooling has become a complex challenge, especially when thermal design power (TDP), a measurement of the maximum power consumed by a chip under normal operating conditions, continues to increase.

Technologies are actively being developed that improve performance of AI applications and models. One technique, wafer-scale integration, is an approach that promises to address the highly demanding performance requirements. Wafer-scale integration can have a particular focus on the data transfer bandwidth requirements of AI and other applications. Wafer-scale integration can include fabricating a monolithic wafer with any number of chips or can include using a wafer as an interposer to couple many chiplets, such as functional chips or other electronic elements. The chiplets can include switching chiplets, processor chiplets, and so on. The chiplets can include AI accelerators; processors and multicore processors; SOCs; application-specific integrated circuits (ASICS); memory chips such as SDRAM, DDR1, DDR2, DDR3, DDR4, DDR5 and high bandwidth memory (HBM); and so on. The chiplets and other elements can be coupled by wiring paths within the wafer interposer. The wafer interposer can be processed using a back-end-of-line (BEOL) wafer process which can include any number of metal layers. These metal layers can be used to couple any AI accelerator to any memory controller on the interposer. The wafer interposer can further include a plurality of waveguides. The waveguides can provide extremely high bandwidth communication between any element included on the interposer such as memory controllers, AI processors, etc. The waveguides can include tapered waveguides.

While interposer metal layers and interposer waveguides can address the performance challenges associated with extremely compute-intensive and high bandwidth applications such as AI acceleration, data transfer associated with the AI applications, and so on, challenges exist for their use in production. For example, a wafer interposer can be brittle and difficult to handle, especially with a plurality of functional chips bonded to a front side. Further, the coplanarity of the wafer interposer can vary, resulting in less-than-optimal electrical connections across the front side and back side of the wafer interposer. Grinding of the interposer, which can enable technologies such as through-silicon vias (TSVs), can thin the wafer interposer, making it still more difficult to handle without cracking. A further challenge arises in the connections between all layers of the wafer-scale integration (WSI) system. For example, chips on the top of the interposer can be mounted using flip-chip techniques via controlled collapse chip connections (C4s), microbumps, and so on to the interposer. However, for delivering power, larger DC power transformers often require soldering to the back side of the interposer. The soldering process can include an oven which can crack or destabilize other C4s or microbumps attached to the interposer. A further complication is the difference in the thermal coefficient of expansion between a typical WSI stack-up, causing various elements to expand at different rates as temperatures rise due to operation. This can cause additional failures within a system. These issues present a substantial technical challenge for the handling, assembly, and operation of wafer interposers.

To address the significant risks while providing power to the wafer-scale integration interposer described above, a photonic wafer-scale interposer with tapered waveguides is disclosed. A photonic wafer-scale interposer (PWSI) is accessed. The PWSI includes a plurality of waveguides. The waveguides can include tapered waveguides. A front side of the PWSI is bonded to at least two chiplets. The WSII includes a plurality of through-silicon vias (TSVs). The TSVs provide connectivity between a front side of the WSII and a back side of the WSII. The at least two chiplets are coupled. The coupling is based on one or more waveguides in the plurality of waveguides. The waveguides can be accessed using couplers. Data is sent, by a first chiplet within the at least two chiplets, to a second chiplet within the at least two chiplets. The chiplets can include switching chiplets. Data that is sent by the first chiplet can include digital data such as digital serial data. The digital data can be converted to optical data using a light source such as a surface-emitting light source. A transition is made between at least one low confinement region and at least one high confinement region. The transition includes the first waveguide. The low confinement region of the waveguide can include a waveguide in which a signal such as a light signal is not tightly confined to the core of the waveguide. The high confinement region of the waveguide can include a waveguide in which a signal is tightly confined within the core of the waveguide, resulting in lower signal loss. The second chiplet receives the data that was sent. A receiver associated with the second chiplet receives the data and provides digital data to the second chiplet.

A plurality of modular power substrates (MPSs) is attached to a back side of the PWSI. The attaching is accomplished using a plurality of conductive connecting materials. The plurality of conductive connecting materials can comprise a plurality of elastomer sheets. The plurality of conductive connecting materials can comprise a plurality of anisotropic conductive films (ACFs). The plurality of conductive connecting materials can comprise a plurality of isotropic conductive adhesives (ICAs). The plurality of conductive connecting materials attaches the plurality of MPSs to a back side of the PWSI. The plurality of conductive connecting materials further provides conduction paths between pads associated with the MPSs and pads associated with the PWSI. The attaching includes compressing, by an isometric grid array (IGA), each conductive connecting material within the plurality of conductive connecting materials. The compressing is based on one or more fasteners such as clamps, screws, spring-loaded fasteners, etc. The fasteners can be configured to provide a desired amount of compression. The attaching couples each MPS within the plurality of MPSs to one or more chiplets within the at least two chiplets. The MPSs can provide power to the one or more chiplets and other electronic elements.

The plurality of MPSs can be connected mechanically to a unified control board (UCB). The connecting mechanically can be based on a plurality of high-power sockets. The high-power sockets can include high-power DC sockets. The UCB can include a plurality of DC-to-DC power converters. The DC-to-DC power converters can convert a higher DC voltage to a lower DC voltage. The lower voltage can enable operation of the chiplets on the PWSI. DC power can be sent, by the UCB, to the plurality of functional chips. The sending is based on the plurality of DC-to-DC power converters, the plurality of MPSs, and the plurality of TSVs. The sending can include delivering the DC power, by the UCB, to the plurality of MPSs. The delivering includes a first voltage conversion. The DC power that was delivered, by the plurality of MPSs, can be transferred to the plurality of functional chips. The transferring includes a second voltage conversion. The second voltage conversion can produce a DC voltage below a threshold such as 1 volt.

A cold plate can be attached to the at least two chiplets and other electronic elements to cool the chiplets and other elements. The cold plate can comprise an inlet plate, a jet-plate, and a fin-plate. Coolant at a first temperature can be sent into at least one inlet nozzle located on the inlet plate. The sending can include spraying the coolant, by the jet-plate, on the fin-plate. At least a portion of the heat that was created can be transferred, by the cold plate, to the coolant that was sent. The coolant can be captured, at a second temperature, from one or more outlet chambers within the jet-plate.

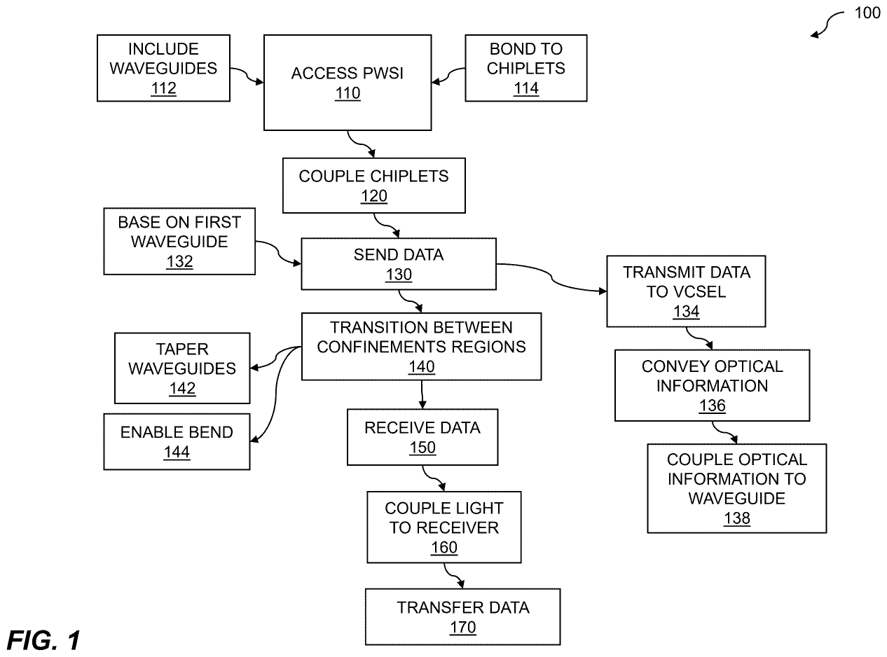

FIG. 1 is a flow diagram for a photonic wafer-scale interposer with tapered waveguides. The flow 100 includes accessing a photonic wafer-scale interposer (PWSI) 110. Wafer-scale integration has been a long-sought goal of integrated circuit design. With wafer-scale integration, an entire wafer such as a silicon wafer could be used to fabricate one large network switch. However, since physical defects in the silicon wafer are distributed across the wafer, portions of circuitry which were fabricated over the defects would likely not function properly. In addition, errors that occur when fabricating the many layers that form the PWSI further create portions of the PWSI that would likely not function. Instead, by attaching or bonding a plurality of chiplets to the PWSI, and forming waveguides within the PWSI, a wafer-scale system such as a network switch or AI accelerator can be achieved. The PWSI can allow chips and chiplets from different manufacturing processes to be included. Further, wafer-level co-packaged optics can be mounted on the PWSI. Thus, the wafer forms the basis of the PWSI and can be used as an interposer to couple the chiplets and other elements. The wafer can be a 300 mm wafer, a 200 mm wafer, or a wafer of another size. The wafer can comprise silicon or another suitable material. In a usage example, another suitable material can include glass. The wafer can include any amount of front-end-of-line (FEOL) processing and/or back-end-of line (BEOL) processing. The processing can be based on silicon-=on-insulator (SOI) or another process.

In the flow 100, the PWSI includes a plurality of waveguides 112. The waveguides can be built in a variety of technologies. In a usage example, a waveguide includes a silicon waveguide, fabricated on a silicon substrate, using a Silicon-on-Insulator fabrication technology. The waveguide can be used to send any type of data, such as AI data, communication packets, switch data requests and/or responses, and so on. In the flow 100, a front side of the PWSI is bonded to at least two chiplets 114. As described previously, the chiplets can comprise AI accelerators, switching chiplets, processors, multicore processors, SoCs, ASICS, memory such as HBM, optical chips such as VCSELs, and so on. The chiplets can include chips designed for sending and receiving data, such as serial data. The serial data can comprise a SERDES format, Universal Chiplet Interconnect Express (UCIe) format, or another serialized data format. The data can include electrical data and/or optical data. The chiplets can include other functional, optical, etc. elements.

In exemplary implementations, the PWSI can comprise a monolithic wafer. The chiplets in this case can comprise a plurality of functional cores that are fabricated on the monolithic wafer. The functional cores can include one or more processors, AI accelerators, ASICS, peripheral interfaces, and so on. The functional cores can include memory. Other memory elements, such as SRAM, can be included in the monolithic wafer. The memory elements can also be fabricated on the wafer. Interconnect can be included on the monolithic wafer to couple any number of the functional cores, memory elements, and so on. The interconnect can comprise any number of metal layers on the wafer and/or one or more waveguides as described.

The flow 100 includes coupling 120 the at least two chiplets, wherein the coupling is based on one or more waveguides in the plurality of waveguides. In a usage example, the chiplets can include switching chiplets and the coupling can be based on a network topology. A network topology can include a ring topology, a star topology, a dragonfly topology, a HyperX™ topology, and so on. In embodiments, the PWSI includes one or more surface-emitting light sources. The one or more surface-emitting light sources can be coupled to a first chiplet. In embodiments, the one or more surface-emitting light sources comprise a light emitting diode (LED). In other embodiments, the one or more surface-emitting light sources comprise a vertical-cavity surface-emitting laser (VCSEL). Other light sources are possible. In some embodiments, the one or more surface-emitting light sources are coupled to the PWSI by micro-transfer printing. The first chiplet can further include an optical receiver. The optical receiver can include a photodiode.

The flow 100 includes sending data 130, by a first chiplet within the at least two chiplets, to a second chiplet within the at least two chiplets. The sending data can include sending digital data. The digital data can comprise point-to-point communications such as AMBA/AXI, serial communications such as PCI-Express (PCIe), or another suitable communications protocol. The digital data can be converted to optical data by a surface-emitting light source. In the flow 100, the sending is based on a first waveguide 132 within the one or more waveguides. In embodiments, the first waveguide is based on reticle stitching. Reticle stitching can include a technique for fabricating a waveguide. In reticle stitching, multiple “reticles” or masks are aligned and exposed onto a wafer such as the PWSI. The aligning and the exposing results in a larger structure such as a waveguide. The waveguide can include a waveguide fabricated in a technology such as a Silicon-on-Insulator (SOI) technology.

In the flow 100, the sending includes transmitting the data 134, by the first chiplet, to a first surface-emitting light source within one or more surface-emitting light sources. The transmitting can be accomplished using interconnect (e.g., wire) on and within the PWSI. In embodiments, the PWSI includes one or more surface-emitting light sources. The surface-emitting light source can be based on a variety of light emitting techniques. In embodiments, the one or more surface-emitting light sources comprise a vertical-cavity surface-emitting laser (VCSEL). The VCSEL can produce a circular beam profile and can have excellent stability with respect to temperature. In other embodiments, the one or more surface-emitting light sources comprise a light emitting diode (LED). The LED can be designed to produce light of various wavelengths. The flow 100 further includes conveying optical information 136, by the first surface-emitting light source, to a first optical coupler. The conveying can be accomplished by directing light from the surface-emitting light source to a coupler associated with the waveguide.

In the flow 100, the first optical coupler couples 138 the optical information to the first waveguide, wherein the optical information is based on the data. The coupling the optical information into the first waveguide can be accomplished using a variety of techniques. In embodiments, the first optical coupler comprises a grating coupler. The grating coupler can diffract light at specific wavelengths into the waveguide. In embodiments, the first optical coupler includes an off-axis diffractive lens. The off-axis diffractive lens, which can bend light significantly off-axis, can bend the light from the emitter to enter the waveguide. In another embodiment, the first optical coupler includes a mirror. The mirror can be fabricated within the PWSI. In further embodiments, the first optical coupler includes a bent waveguide. The bent waveguide can be fabricated within the PWSI. The bent waveguide can enable transfer of light from the surface-emitting light source associated with the first chiplet into the waveguide using the same materials as the waveguide.

The flow 100 includes transitioning 140 between at least one low confinement region and at least one high confinement region, wherein the transitioning includes the first waveguide. A low confinement region of a waveguide can include a region where light within the waveguide is not tightly confined within the waveguide. That is, a portion of the light can “leak out” or extend beyond the core of the waveguide. A high confinement region of a waveguide can include a region where the light within the waveguide is tightly confined to the core of the waveguide. The transitioning can occur between the waveguide and a coupler, different size regions of the waveguide, and so on. In the flow 100, the transitioning can include tapering 142 the waveguide. The tapering can be accomplished using a variety of techniques. In embodiments, the tapering can include adiabatic tapering. For adiabatic tapering, the waveguide gradually tapers over a portion of the waveguide. Adiabatic tapering can accomplish a smooth transition between cross-sectional sizes of a waveguide with minimal light loss during the length of the taper. The adiabatic taper can be formed based on a variety of fabrication techniques. In embodiments, the tapering is based on three-dimensional (3D) lithography. The 3D lithography can form the adiabatic taper layer by layer. In embodiments, the tapering is based on three-dimensional (3D) lithography. The 3D lithography can enable fabrication of the tapered waveguide within a material such as polysilicon. In embodiments, the tapering is based on greyscale lithography. Grayscale lithography, which can include a microfabrication technique, can use gray values to create a 3D structure such as the tapered waveguide. The grayscale lithography can use light intensities of varying values to create 3D microstructures such as the 3D waveguide taper. In embodiments, the transitioning includes a second waveguide in the plurality of waveguides, wherein the transitioning is based on evanescent coupling. Evanescent coupling (described below) takes advantage of the portion of a light signal that extends beyond the core of a low confinement waveguide. By placing a second waveguide in close proximity to the first waveguide, the evanescent portion of the light in the first waveguide extends into the second waveguide, thus coupling the light signal between the first waveguide and the second waveguide. In the flow 100, the transitioning enables a bend 144 in the first waveguide. A bend in the first waveguide can enable coupling of optical data from a surface-emitting light source into the waveguide.

The flow 100 includes receiving 150, by the second chiplet, the data that was sent. The second chiplet can receive the data that was sent from the first chiplet by accessing the optical data that was sent through the first waveguide. The data that is received can include serial optical data. In the flow 100, the receiving includes coupling 160 the optical information, by a second optical coupler, from the first waveguide, to an optical receiver. The optical receiver can include an element within the second chiplet, an element coupled to the second chiplet, and the like. The receiver can include an electro-optical receiver. In embodiments, the second optical coupler can include a grating coupler. Discussed previously, the grating coupler can couple light from the waveguide to the receiver using a grating. The grating is pitched such that light at a specific wavelength can be transferred from the waveguide to the receiver with minimal signal loss. In other embodiments, the second optical coupler can include a photodiode. The photodiode can convert the serial optical data to serial electrical data. The second optical coupler could also include a Photodarlington transistor. The flow 100 further includes transferring, by the optical receiver, the data 170 to the second chiplet. The data can be sent as serial data, parallel data (e.g., as bytes, words, etc.) by the optical receiver to the second chiplet. The sending can be accomplished using interconnect associated with one or more layers of interconnected on and within the PWSI.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors. Various embodiments of the flow 100 can be included in an apparatus for power delivery or system that is configured to deliver power.

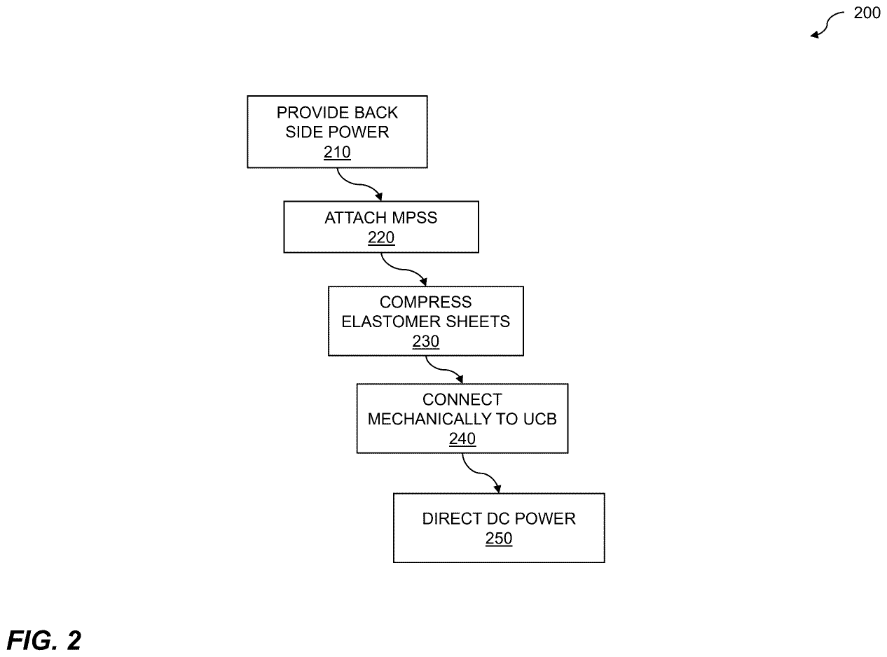

FIG. 2 is a flow diagram for providing power. Integrated circuits or chips such as chiplets, surface-emitting light sources, functional chips, and so on can be bonded to a photonic wafer-scale interposer (PWSI). The use of the PWSI supports wafer-scale integration (WSI), which is particularly useful to supporting the processing requirements of computationally intensive applications such as artificial intelligence (AI) acceleration, machine learning applications, and the like. The chiplets that can enable high-speed data transfer using tapered waveguides, and the functional chips that execute the computationally intensive applications, require significant amounts of power during operation. The power, which includes DC power, must be provided chiplets, light sources, and functional chips. The power can be provided using modular power delivery techniques. As the chiplets, light sources, and functional chips are operating, prodigious amounts of excess heat can be generated by these electronic elements. At least a portion of the generated heat can be transferred to a coolant that can be sent to a cold plate. Thus, providing DC power enables photonic wafer-scale integration with tapered waveguides.

Described previously, a photonic wafer-scale interposer (PWSI) can be accessed. A wafer, such as a silicon wafer or other semiconductor wafer, can be used as an interposer. The interposer can be bonded to a plurality of integrated circuits such as chiplets. The interposer can be used to achieve wafer-scale integration. Wafer-scale integration has been a long-sought goal of integrated circuit design. Wafer-scale integration, once achieved, would enable use of an entire wafer such as a silicon wafer on which one large integrated circuit could be fabricated.

However, since physical defects in the silicon wafer are distributed across the wafer, portions of circuitry fabricated over the defects will most likely not function properly, if at all. In addition, errors that occur when fabricating the many layers that form the integrated circuit further create portions of the integrated circuit that will likely not function. Instead, by attaching a plurality of integrated circuits to the PWSI, wafer-scale integration can be achieved.

The wafer can include a 300 mm wafer, a 200 mm wafer, or a wafer of another size. The wafer can comprise silicon or another suitable material such as a semiconductor wafer. The wafer can include any amount of front-end-of-line (FEOL) processing and/or back-end-of line (BEOL) processing. The processing can be based on Complementary Metal-Oxide-Semiconductor (CMOS), Silicon-on-Insulator (SOI), or another process. A front side of the PWSI can be bonded to a plurality of functional chips. The PWSI can have a front side and a back side onto which elements such as the chiplets and other circuit elements can be attached. The chiplets and other chips can include general purpose chips such as processor chips, multiprocessor chips, application-specific integrated circuits (ASICS), memory chips, and so on. The chips can further include specialty processing chips such as accelerators for artificial intelligence training and inferencing, machine learning, and the like. The PWSI includes a plurality of through-silicon vias (TSVs). A TSV can include an electrical connection that completely passes through the front side and the back side of a wafer such as a silicon wafer or a die. The plurality of TSVs is oriented vertically in order to enable connections, power delivery, and so on between the front side of the wafer and the back side of the wafer. Chips such as the functional chips can be positioned such that connections to the chips align with the TSVs. In some examples, a wafer can be ground to enable TSV processing with repeatable shapes and parasitic characteristics.

Chips such as chiplets, functional chips, and so on can be bonded to a photonic wafer-scale interposer (PWSI). The use of the PWSI supports wafer-scale integration (WSI), which is particularly useful to supporting the processing requirements of computationally intensive applications such as artificial intelligence (AI) acceleration. The chiplets and other electronic elements that execute the computationally intensive applications require significant amounts of power during operation. The power, which includes DC power, must be sent or transferred to the functional chips. The power can be provided using modular power delivery techniques. A PWSI can be brittle and difficult to handle, especially with a plurality of functional chips bonded to a front side. Further, the coplanarity of the PWSI with respect to the UCB can vary, resulting in less-than-optimal electrical connections across the front side and back side of the PWSI. Additionally, to support of reliable manufacture of the TSVs, the interposer can be ground and/or polished to a thinness that can support fabrication of the TSV. This technique can thin the wafer, making it more difficult to handle without cracking, especially with the additional weight of front side chiplets and other electronic elements. Thus, the MPSs must be supported or stiffened in order to protect the wafer-scale integration interposer from cracking or fracturing.

The flow 200 includes providing power 210 to the at least two chiplets, wherein the providing is based on a back side of the PWSI, and wherein the PWSI includes a plurality of through-silicon vias (TSVs). The providing power can include providing DC power. The chiplets, surface-emitting light sources, functional chips, etc. require power such as DC power to operate. Described previously, the power can be provided by attaching one or more power modules (described below) to a backside of the PWSI. In order for the power to reach the chiplets, light sources, and other elements, the power can be provided from the back side of the PWSI to the front side of the PWSI using the plurality of TSVs.

The flow 200 includes attaching 220, to the back side of the PWSI, a plurality of modular power substrates (MPSs), wherein the attaching is based on a plurality of elastomer sheets, wherein the attaching includes compressing, by an isometric grid array (IGA), each elastomer sheet within the plurality of elastomer sheets, and wherein the attaching couples each MPS within the plurality of MPSs to one or more chiplets within the at least two chiplets. The attaching can comprise an electrical connection. A modular power substrate can include one or more electrical elements, connectors, and so on. In embodiments, the attaching is based on one or more controlled collapse chip connection bumps (C4s). In the C4 technique, solder balls are placed on connections or pads at the topmost layer of the functional chips. The chips are flipped using a flip-chip technique so that the C4 bumps align with the TSVs discussed previously. The electrical elements can include DC-to-DC converters. Any number of voltage conversions can be included so that the chiplets and other electrical elements receive power at an appropriate voltage for operation. In a usage example, the first voltage conversion is accomplished by the plurality of DC-to-DC power converters. The connectors can include a high-power connector and a plurality of rigid-flex strips. The substrate associated with an MPS to which are mounted the electrical elements, connectors, and so on can include a variety of materials. In a usage example, one or more MPSs within the plurality of MPSs can include an organic substrate. An organic substrate can be based on organic materials, such as organic materials used to manufacture printed circuit boards. The organic substrate materials can include paper cores impregnated with phenolic resin; woven or unwoven glass cloth impregnated with epoxy or cyanate ester, among others; natural fibers; etc. In another usage example, one or more MPSs within the plurality of MPSs can include an inorganic substrate. An inorganic substrate can be based on silicon, glass, etc.

Each MPS is coupled to one or more chiplets, electrical elements, etc. The coupling between each MPS and the one or more functional chips can be accomplished using the TSVs. The plurality of MPSs can be based on a form factor mirroring one or more corresponding functional chips, within the plurality of functional chips, on the front side of the PWSI. The form factor can include a square form factor, a rectangular form factor, and so on. In a usage example, the form factor of the MPS is smaller than the form factor of the PWSI. The flow 200 includes compressing 230, by an isometric grid array (IGA), each elastomer sheet within the plurality of elastomer sheets, and wherein the attaching couples each MPS within the plurality of MPSs to one or more chiplets within the at least two chiplets. A grid such as an isometric grid array (IGA) can accomplish attaching of modular power substrates (MPSs) to a back side of the PWSI. The IGA can include a compression plate. The IGA can be stiffened, where the stiffening can be based on a plurality of reinforcement structures. The stiffening the IGA can be used to establish substantially equal compression across the MPSs. The stiffening can enable planar compression of the MPSs, and thus planar compression of conductive connecting materials, such as elastomer sheets, used to couple the MPSs to the PWSI. The conductive connecting materials further provide conduction paths between the MPSs and the PWSI. The reinforcement structures can also reduce the risk of fracturing of the PWSI during handling, assembly, functional operation, and so on. In other disclosed implementations, the attaching is based on laser-assisted bonding (LAB). LAB is a technology which can heat and reflow one or more C4, micro bump, etc. connections without the need for a reflow oven which can bend, crack, break, etc. existing connections.

The flow 200 further includes connecting mechanically 240 the plurality of MPSs to a unified control board (UCB), wherein the connecting mechanically is based on a plurality of high-power sockets, and wherein the UCB includes a plurality of DC-to-DC power converters. In some examples, the UCB can comprise one or more control boards. Each control board can include the plurality of DC-to-DC power converters. The connecting mechanically can be accomplished using plug-and-socket connectors, terminals, cables, and so on. In a usage example, the connecting mechanically an MPS to the UCB can be accomplished using a DC power connector and a plurality of rigid-flex strips. The connecting mechanically can be based on a high voltage socket. The UCB can include one or more digital controller chips to control the DC-to-DC power converters. The digital control circuits can comprise a processor, a multiprocessor, a microcontroller, and so on. The digital control circuits can control the DC-to-DC power converters.

The connecting mechanically accommodates a maximum lateral displacement of the UCB due to thermal expansion during operation. Physical components such as substrates, PWSIs, etc. can expand when heated, based on a coefficient of thermal expansion associated with each material. A coefficient of thermal expansion of the UCB can be different from a coefficient of thermal expansion of the PWSI. The difference in expansion coefficients can cause connectors to disconnect, C4s to crack, materials to experience physical strain and subsequent damage such as a fracture, etc. Thus, if the UCB is directly mechanically connected to a PWSI, the lateral displacement due to differences in thermal expansion can cause mechanical failure. Recall that the MPSs can be modular and can be based on a form factor mirroring one or more corresponding functional chips on the front side of the PWSI. The modularity of the MPSs can provide a flexible power delivery system to the chiplets and other electronic elements which can accommodate different movements of the PWSI and UCB due to thermal expansion. For example, an MPS at one side of the PWSI can be decoupled from an MPS on the other side of the PWSI, thus accommodating various movements across the PWSI and UCB. Recall also that the MPSs can be mechanically connected to the UCB via a high-power socket, which can couple the DC-to-DC converters within the UCB to the MPSs. The high-power socket can provide flexibility to accommodate lateral movement between the UCB and the MPS (which is attached to the PWSI).

DC power can be delivered by the UCB to the plurality of MPSs. The delivering DC power can be accomplished by the plurality of DC-to-DC converters included on the UCB. The delivering DC power can include delivering DC power to a subset of MPSs. The delivering DC power can be accomplished by matching one or more DC-to-DC converters to one or more MPSs. Interconnection between the DC-to-DC converters matched with one or more respective MPSs can be accomplished using interconnect associated with the UCB. The DC power that is delivered can include a range for the DC voltage. The range of DC voltage can include a percentage of a target voltage, an allowable operating range of DC voltage, and the like. In a usage example, the voltage range can include 48 volts to 54 volts, inclusive. The delivering can include a first voltage conversion. The first voltage conversion can include a DC-to-DC voltage conversion. The result of the DC-to-DC voltage conversion can include a DC voltage higher than the input DC voltage or a DC voltage lower than the input DC voltage. The first voltage conversion can be accomplished using the one or more DC-to-DC converters. The DC-to-DC converters can include a plurality of DC-to-DC converters connected to the UCB.

The flow 200 further includes directing 250 DC power, by the UCB, to the at least two chiplets, wherein the directing is based on the plurality of DC-to-DC power converters, the plurality of MPSs, and the plurality of TSVs. The one or more chiplets can obtain the directed power using interconnect, contacts, and so on. The chiplets and other electronic elements can also use interconnect and contacts to receive and send data, instructions, control signals, etc. The transferring can further include a second voltage conversion. The second voltage conversion can be accomplished using one or more converters such as DC-to-DC converters associated with the MPSs. The second voltage conversion can produce a voltage that can be used directly to operate one or more chiplets. The second voltage conversion can attain a voltage less than the voltage resulting from the first voltage conversion. The second voltage conversion can result in a voltage less than a threshold. The threshold can include a target voltage, an operating voltage, and so on. In a usage example, the threshold is 1 volt. The transferring is based on the plurality of TSVs. The transferring can include transferring DC power, receiving and sending data, sending and receiving functional chip instructions and control signals, etc.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors. Various embodiments of the flow 200 can be included in an apparatus for power delivery or system that is configured to deliver power.

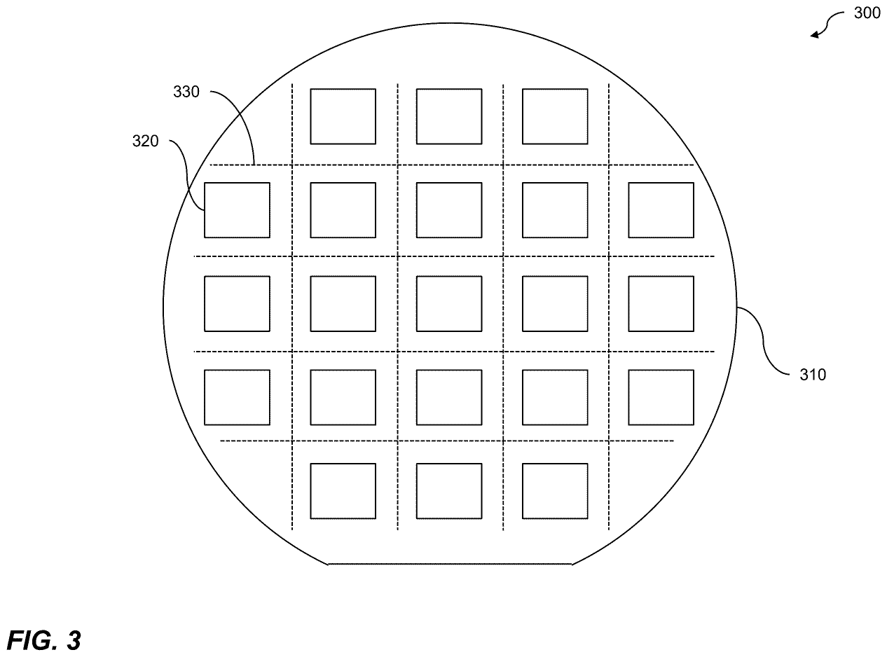

FIG. 3 illustrates a wafer with multiple die. A semiconductor wafer such as a silicon wafer is used in the fabrication of electronic circuits. Other semiconductor materials such as germanium, silicon carbide, indium phosphide, gallium nitride, etc. can also be used. The wafers that are used are obtained in various sizes. One common wafer size includes a 300 mm silicon wafer. Integrated circuits or “chips” can be fabricated on the surface of the wafer by applying, removing, implanting, etc. various layers. The layers are applied to the wafer using techniques that can include diffusion, deposition, etching, planarization, and so on. The numbers of layers applied to the wafer can include dozens of layers, hundreds of layers, and so on. The layers can include active areas (e.g., transistors), polysilicon, metal, contacts, vias, and so on. The circuits are called “die” during fabrication. The die can include a plurality of similar circuits or can include two or more different circuits or “projects.” The similar circuits and the different projects can include processors, memories, mixed-signal chips, and so on. The multiple die that can be fabricated on the semiconductor wafer can include accelerators for artificial intelligence and for machine learning. The multiple die can be used to enable photonic wafer-scale interposer with tapered waveguides. Reinforcement structures can be added to stiffen elements such as modular power supplies (MPSs). The reinforcement structures can be glued, deposited, or otherwise applied. The reinforcement structures maintain a coplanarity of each MPS in the plurality of MPSs.

The figure 300 shows a wafer with multiple die. A wafer can be based on a monocrystalline semiconductor material. The semiconductor material can include a group IV material such as silicon, a group III-V material such as gallium arsenide, and so on. The die on the wafer shown are substantially similar in size. However, the die can be substantially different in size. A system can depend on a certain number of functional die. For instance, an artificial accelerator used for training a large language model (LLM) to be executed on a neural network (NN) can require a large number of functional die. The die can be comprised of AI accelerators, ML accelerators, and so on. Since a wafer will contain defects randomly distributed across the wafer, some of the die fabricated on the wafer will be affected by the wafer defects and will not function properly. By fabricating multiples of the die, the probability of fabricating at least one functioning chip increases. Further, because the presence or absence of circuits or die on the wafer can influence successful fabrication of a given die, a wafer can be “covered” with circuits for fabrication. Because of the shape of the wafer, which is typically round with at least one flat edge to aid alignment, some of the circuits may not be fully contained within the boundaries of the wafer. The resulting “partial” circuits or die will not function fully or at all. In some cases, the partial die may be usable in other applications.

A wafer is shown 310. The wafer can include multiple die such as die 320. The multiple die can be replicas of the same chip. In some cases, the multiple die can be different die, such as SRAM die. The die on the wafer can all be fabricated using the same fabrication technology. If any die requires different fabrication technologies, then that die must be fabricated on a different wafer. While 21 die are shown on the wafer, in practice any number of die can be present. The number of die will depend on the size of the wafer and the size of the die. When fabrication steps, of which there can be many, are completed, the die can be separated. The figure shows a plurality of dashed lines such as line 330. The dashed lines represent scribe lines or kerf associated with the wafer. A saw, a laser, etc. is used to slice the wafer into liberated, individual die. Since the saw or other cutting device has a finite width, some wafer material is lost due to the width of the saw or cutting device. As a result, any structures such as test structures used to track processing steps during fabrication are lost.

While multiple die are shown in the diagram, the desire to further push the size of individual die has continued at a rapid pace. As one reference point, a packaged processor chip that is larger than 35 mm on a side has become common. However, as die on a wafer become larger, the risk of individual die being impacted by defects in the wafer, or defects associated with any of the many fabrication steps, increases. How, then, could one produce even larger chips? One suggestion that has long been proposed is to use the “entire” wafer to form a single large chip or “super chip.” In addition to producing the one chip on the wafer, packaging could potentially be reduced since the packaging would involve the one chip instead of a typical suite of chips, where each chip requires its own packaging. Wafer scale integration or WSI has been proposed as particularly well suited to applications that demand extensive data processing.

Examples proposed that could benefit from WSI have included computer architectures appropriate for massively parallel supercomputers, and computationally intensive applications such as machine learning and deep learning. However, successful fabrication of a single chip across an entire wafer is an extremely difficult undertaking. Noted above, the widespread and random distribution of defects and other variations such as warpage across a wafer render the ability to build one “super-circuit” elusive. Also, circuit redundancy becomes a major design issue. Not only are redundant circuits that can be switched in to replace defective circuits necessary, but the locations of the redundant circuits are also critical. Note that the redundant circuits must be connected in place of the defective circuits, and that wiring on an integrated circuit is extremely expensive in terms of real estate. As a result, the placement of the redundant circuits must be carefully considered to conserve wafer real estate and to reduce wiring complexity.

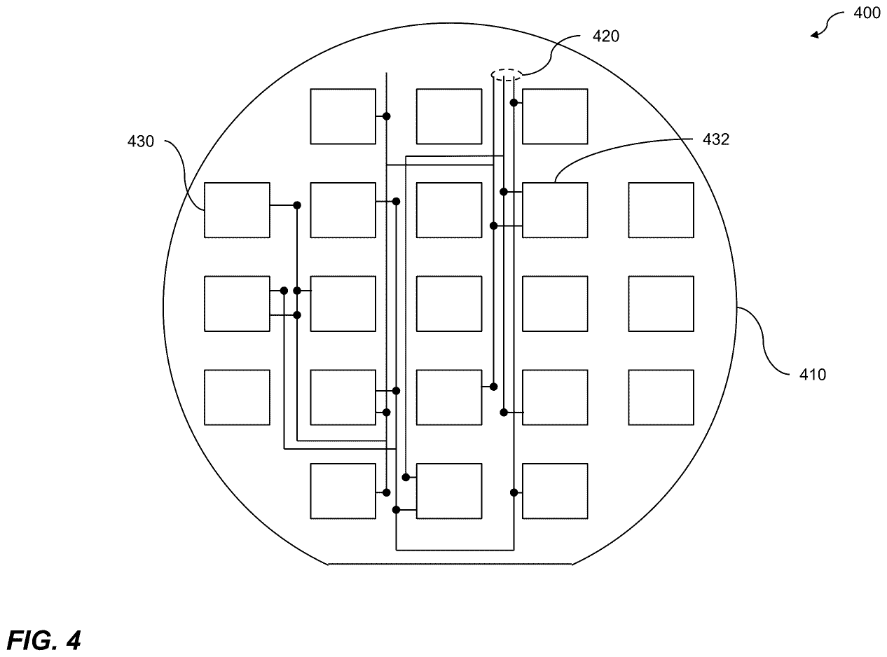

FIG. 4 illustrates inter-die interconnect for wafer-scale integration. Discussed previously and throughout, the demand for ever larger integrated circuits that can meet increasingly intensive processing demands has been stymied by the difficulty of producing large, single chips. One of the fundamental difficulties of producing a large chip, such as a wafer-sized chip, is that defects are randomly distributed across a wafer on which the large chip would be produced. Further, defects, such as disconnects in wiring, variations in oxide (insulator) thicknesses, open-circuit contacts, varying doping profiles, and so on, can be introduced during the fabrication process. One possible approach to “wafer-scale” integration is to continue to fabricate circuits on the wafer. Then, instead of cutting the wafer to access the individual dies, the wafer remains whole. By adopting an approach such as this one, the kerf, previously lost to the cutting of the wafer into the individual die, can be used for interconnect channels. Recall that interconnect on a wafer consumes wafer real estate that cannot otherwise be used for circuitry. By capturing the real estate previously lost to the kerf, additional wafer real estate is captured that can be used for interconnect. The interconnect in the kerf is particularly appropriate for long-haul connections, such as connections between individual die on the wafer. Since the wafer can be thinned during fabrication to enable vias, called through-silicon vias, to provide connections between a front side of the wafer and a back side of the wafer, the wafer can be reinforced to maintain wafer integrity. Various elements can be mounted on, connected to, and otherwise coupled to the wafer. The various elements can include photonic elements. The inter-die interconnect for wafer-scale integration enables a photonic wafer-scale interposer with tapered waveguides.

The figure 400 illustrates use of wafer real estate, otherwise lost to scribe lines or kerf for inter-die interconnect, for wafer-scale integration. A wafer 410 is shown on which multiple die, or chips, are distributed. The die are fabricated together on the wafer. That is, each of the die on the wafer is fabricated based on the same processing steps. Since the individual die will not be separated from the wafer using a cutting technique, the kerf area of the wafer can be used for interconnect. Other areas of the die can also be used for interconnect. The interconnect 420 can be placed in wiring channels or routes, where the wiring channels are realized in what would formerly have been the kerf. The wiring channels include wafer real estate in which interconnecting wire can be placed. The interconnect can be fabricated while the various die on the wafer are fabricated. The interconnect can include a plurality of wiring layers. The various layers can be interconnected using contacts, vias, and so on. In the figure, a few example interconnecting runs are shown. The various die on the wafer can make connections to the wiring channels. In the figure, die 430 can use the wiring channels to connect to die 432.

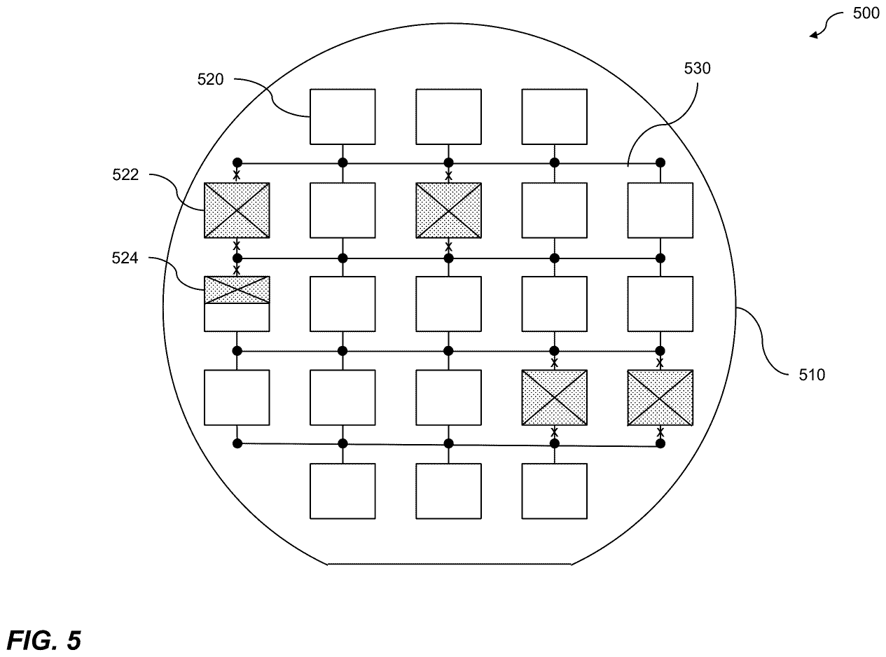

FIG. 5 shows inter-die interconnect and redundancy for wafer-scale integration. Building on the previous discussions of techniques including fabricating redundant die on a wafer and of using the kerf for interconnect, a technique for wafer-scale integration (WSI) can be based on fabricating redundant die on the wafer, and selecting the working die for use by a system based on WSI. Working die can be selected, while non-working die, partial die, and other substandard die can be electrically ejected from the system by deselecting the die. The deselecting can include disabling wired connections to the unused die, physically “blowing” connections (e.g., a fuse) to the unused die, and so on. The remaining functioning die can be interconnected using inter-die interconnect to form a system on the wafer. The system on the wafer can achieve the desired objective of wafer-scale integration. Power, data, control signals, and so on can be provided to the selected, working die. Due to the size of the wafer on which the interconnected die are fabricated, the wafer can be subject to warping, cracking, breakage, and so on. The wafer can be supported or stiffened such that risks of damage to the wafer and the die on the wafer can be minimized. Further, connections between the wafer and elements such as power supplies, DC-to-DC converters, controllers, photonic elements, and so on can be established using selectively conducting elastomer sheets. Inter-die interconnect and redundancy to support sending data are enabled with a photonic wafer-scale interposer with tapered waveguides.

The figure 500 shows redundant die and inter-die interconnect. A wafer is shown 510. The wafer is populated with multiple die such as die 520. A number of the die shown can be redundant. Some of the redundant die will include defects, can be incomplete, can miss specifications, or can otherwise fail. The defects can be associated with the wafer on which the die are fabricated, associated with one or more processing steps for fabricating the die, and so on. This can result in die that are not operational, such as die 522. Recall that die can be fabricated on the wafer in order to ease some fabrication complexities, and that some of the added die can include partial die such as die 524. The failed die and the partial die can be excluded from a system formed by wafer-scale integration (WSI). In some cases, a die such as 524 can be partially functioning. The portion of the die that is functioning can be included in the WSI, while the portion of the die that is not functioning can be excluded. The functioning die can be inter-connected using inter-die interconnect 530. The inter-die interconnect can include multi-layer interconnect. The inter-die interconnect can be placed between the die associated with the multiple projects. Functioning die can be connected to the inter-die interconnect, while non-functioning die can be disconnected from the inter-die interconnect.

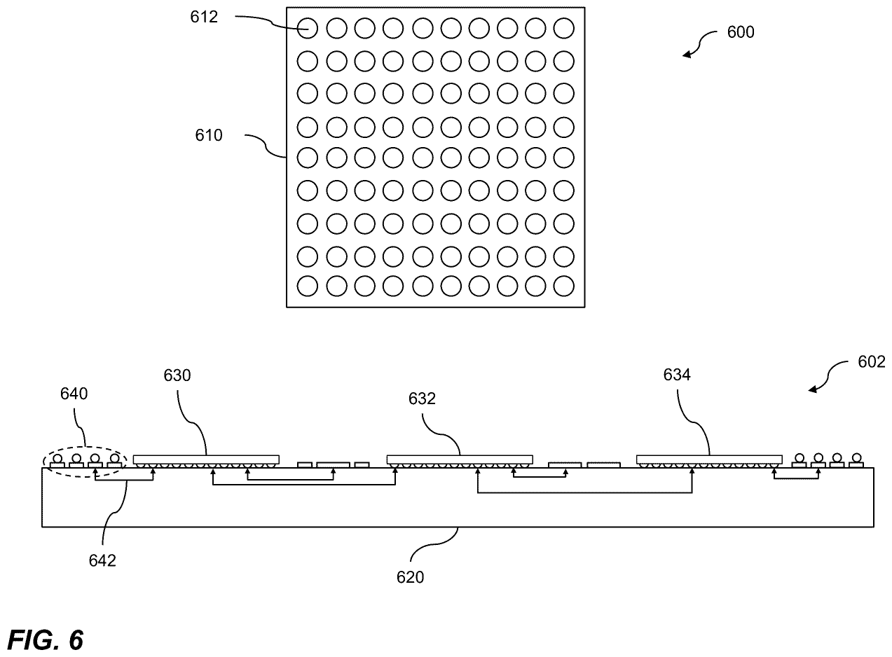

FIG. 6 illustrates a flip-chip and interposer with flip-chips for wafer-scale integration. One technique that can be used to approach the benefits of wafer-scale integration is to attach more than one chip to a common substrate or interposer. The interposer can include a photonic interposer. The substrate can include a wafer, a carrier, a circuit board, and so on. To accomplish such a technique, all interconnections to a circuit or chip, including data connections, control and signal connections, power connections, and so on, can be made at the top layer of the chip. The connections at the top of the chip replace the traditional placement of pads at the periphery of the chip. To connect the top connections of the chip to the interposer, solder balls are placed on the top connections and the chip is inverted or “flipped.” The solder balls, when melted, can connect the top connections of the chip to corresponding connections or pads on the interposer. Further chips can be similarly flipped and connected to additional corresponding connections on the interposer. One challenge to the flip-chip technique is providing power to the chips. The power can be provided using back side power delivery for wafer-scale integration with modular power substrates (MPSs). A further challenge to the flip-chip technique is that the aggregate weight of the flipped chips can be sufficient to pose a risk to the delicate wafer or interposer. The wafer can be stiffened in order to protect it from the weight of the flipped chips. The wafer can further be stiffened using one or more reinforcement structures. The plurality of reinforcement structures can enable planar compression of each elastomer sheet within a plurality of elastomer sheets. The elastomer sheets enable attachment of elements such as the plurality of MPSs to a back side of a photonic wafer-scale interposer (PWSI). The PWSI includes tapered waveguides. Sending data is enabled by the photonic wafer-scale interposer with tapered waveguides.

The figure 600 includes an example flip-chip. Discussed previously, the flip-chip 610 differs from a traditional chip in that the connections to the flip-chip are made at the top of the chip rather than to pads located at the periphery of the chip. A top view of a flip-chip is shown. The top can include pads that can be connected to corresponding pads on a multi-chip module, a circuit board, an interposer, and so on. An example contact or pad 612 is shown. Multiple pads can be distributed across the top of the flip-chip. The pads can be oriented to correspond with receiving pads on the interposer. An array of pads is shown. In a usage example, a subset of pads can be required to connect the flip-chip to the interposer. Thus, required pads are present at the top of the flip-chip, while the unused pads can be omitted from the top of the flip-chip.

The illustration 602 shows an example interposer. As discussed previously, the interposer 620 can include a wafer, a carrier, a circuit board, and so on. One or more flip-chips can be attached to the interposer. In the figure, the flip-chips can include a first flip-chip 630, a second flip-chip 632, a third flip-chip 634, and so on. While three flip-chips are shown, other numbers of flip-chips can be attached to the interposer. In a usage example, the flip-chips can be attached to the interposer in a grid pattern. In addition to serving as a placement location for the flip-chips, the interposer can provide interconnect. The interconnect can be used to provide signals such as control signals, data, and so on to the flip-chips. The interconnect can further provide power to the flip-chips. Depending on the interposer used to receive the flip-chips, the interposer can include one or more layers of interconnect. The interconnect can include interconnect at a top surface of the interposer such as top surface interconnect 640. The interposer can further include additional layers of interconnect. The additional layers of interconnect can be fabricated on the interposer. The additional layers of interconnect can be isolated from each other using an insulating layer between the conducting interconnect layers.

An example “lower layer” connection 642 is shown.

The use of flip-chips attached to an interposer can enable multichip module (MCM) techniques. A multichip module can refer to a substrate, carrier, circuit board, interposer, etc. onto which multiple ICs can be placed. The multiple ICs can be attached to the interposer, and the multiple ICs can be wired together using interconnect provided by the interposer. The interconnect associated with the interposer can provide power, control signals, and data between and among the ICs that are attached to the interposer. The power can be provided using modular power techniques. Depending on the particular type of MCM, the interposer can further include discrete components such as discrete resistors, discrete capacitors, discrete inductors, discrete diodes, etc. The interposer further includes wiring for interconnecting ICs and the discrete components, if any. The MCM can be packaged and used as if it were a single IC on a board such as a circuit board within a system. MCMs have also been referenced as heterogeneous integration circuits and hybrid integrated circuits. A principal advantage of using MCMs is that multiple electronic components can be enclosed in a single “chip,” thereby improving modularity of a system design. Also, the use of MCMs can improve IC yields over ICs produced using monolithic IC design methodologies.

There can be several varieties of MCMs, where the MCM varieties are typically differentiated by size, complexity, design methodology, and so on. At one end of the complexity scale, an MCM can include standard off-the-shelf ICs. The ICs can be attached to a circuit board such as a printed circuit board and can be used in place of an existing chip or package of chips. The printed circuit board can be designed to match the size and pin-out of the existing chip or package of chips. An MCM can also be a complex element. The complex MCM can be based on one or more fully customized IC packages. The fully customized IC packages can be used to integrate multiple IC dies (e.g., unpackaged ICs) onto a substrate that provides interconnection among the dies. Because of the wiring requirements of the multiple IC dies, the substrate typically includes high density interconnection (HDI). The substrates that are used for the MCM can include thin films for interconnects (wires) and dielectrics (insulators); thick films that enable more than one layer of interconnect and ceramic; and substrates that include laminates based on organics or plastics. The MCM based on thin films of interconnects and dielectrics can result in the highest circuit densities.

The MCM design concepts described previously suggest promising leads for implementing wafer-scale integration ICs. Multiple circuit dies could be fabricated within the same wafer. The wafer could further include built-in self-test (BIST), circuit redundancy to provide spare parts, and “self-rerouting.” The self-rerouting can “reroute” around defective, incomplete, or failed elements and can wire in known good spare parts. In order to enable such capabilities, a significant number of interconnect layers would be required for WSI. Interconnect layer counts of approximately ten layers have been predicted. In order to implement WSI in a cost-effective manner, several techniques have been proposed, such as using an artificial neural network to develop a programmable topology, using a multichip-scale package, and so on.

Another technique that is being developed to enable wafer scale integration is based on the use of a silicon interposer, as discussed above. The interposer can further include an interposer based on other materials such as glass. The silicon interposer, which can be a wafer, can be used to provide interconnections among a wide variety of components. The components include integrated circuits (chips), chiplets, power supplies, power converters, discrete electrical components, and so on. The interposer provides connection points that can be used to mechanically and electrically mount the chips, chiplets, etc. The interposer can be formed from inorganic materials such as glass or silicon, or organic materials such as those used to manufacture printed circuit boards. The electrical connections can be set to a pitch to simplify the attaching of the electrical elements. The electrical connections can be based on standardized manufacturing techniques such as using solder balls, micro-bumps, controlled collapse chip connection (C4) bumps, and/or electroplated bumps. The bumps on a chip are produced on the “top” side of a wafer (e.g., the non-substrate side) as a final processing step for the wafer. To mount the chips to the interposer, the chips are “flipped” using a flip-chip technique. The bumps at the top of the chips connect to pads on the interposer. The interposer can enable connections from the flip-chip to a standard connection arrangement such as a grid. The interposer can further provide one or more layers of interconnect according to the process used to manufacture the wafer. Thus, higher densities, higher bandwidth, and faster speeds can be achieved. The layers of interconnect are used to provide power and ground, control signals and data, and so on.

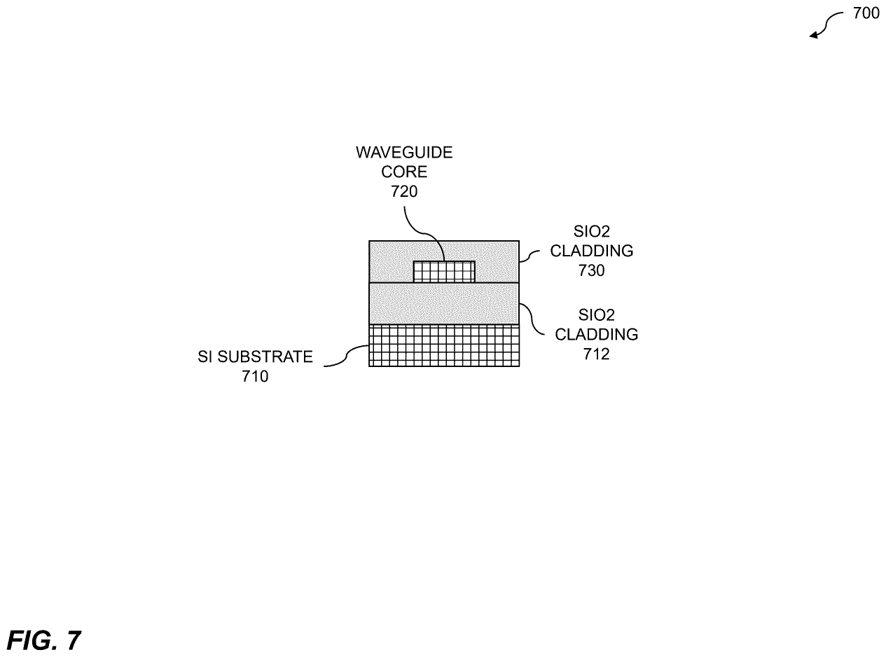

FIG. 7 is an example of a waveguide cross-section in Silicon-on-Insulator (SOI) technology. A waveguide can be used to transfer a signal such as an optical signal between two elements associated with a switch such as a data switch. The waveguide can be fabricated within a monolithic wafer which includes one or more functional chips. The waveguide can be fabricated within a photonic wafer-scale interposer (PWSI), where the PWSI can be based on a wafer such as a silicon wafer, a glass wafer, and so on. The wafer can be used as a substrate for the PWSI. A plurality of waveguides can be fabricated within the PWSI in order to enable high speed, high bandwidth communications between chiplets, even chiplets separated by a long distance on the PWSI. The waveguides can be tapered. The chiplets can be associated with a switch such as a network switch. The plurality of waveguides enables a photonic wafer-scale interposer with tapered waveguides.

The cross-section of an example waveguide fabricated in a Silicon-on-Insulator (SOI) technology is shown 700. A silicon substrate 710 is obtained. The silicon substrate can include a silicon wafer, where the silicon wafer can include a 200 mm silicon wafer, a 300 mm silicon wafer, and so on. A silicon dioxide (insulator) layer 712 can be grown, deposited, or otherwise formed on the silicon wafer. One or more waveguides, such as waveguide 720, can be formed on the insulator layer 712. An insulator layer 730 can be placed over the one or more waveguides. The insulator layer can be planarized in order to enable fabrication of further elements. The waveguide can conduct light in order to establish optical communications between an optical source and an optical receiver within the PWSI.

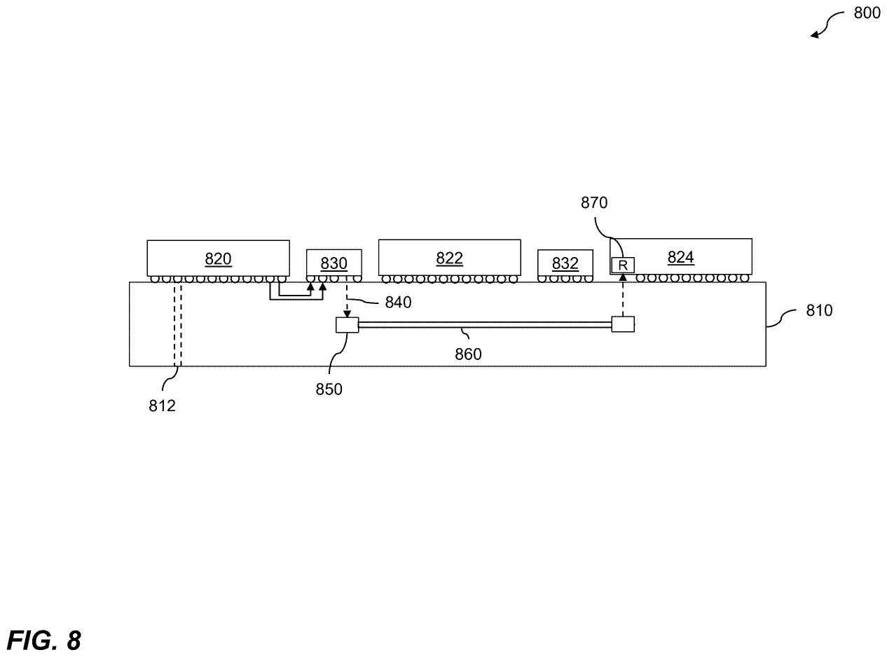

FIG. 8 is a cross-section for a photonic wafer-scale interposer (PWSI) with chiplets. The PWSI can include electronic elements, photonic elements, and so on. The photonic wafer-scale interposer (PWSI) 800 includes a plurality of waveguides. A front side of the PWSI is bonded to at least two chiplets. The PWSI enables a photonic wafer-scale interposer with tapered waveguides. The chiplets can be connected, attached, or otherwise coupled to the PWSI 810. At least two chiplets such as chiplet 820, chiplet 822, and chiplet 824 are bonded to the front side of the PSWI 810. The chiplets can be bonded to the PWSI via micro-bumps, controlled collapse chip connections (C4s), and so on. The PWSI can include a plurality of through-silicon vias (TSVs) such as TSV 812. A TSV can include an electrical connection that completely passes through a wafer such as a silicon wafer, a glass wafer, or a die. The plurality of TSVs, if present, can be oriented vertically in order to enable connections between the front side of the wafer and the back side of the wafer. A chiplet can be coupled to a light source, where the light source can include a surface-emitting light source. The PWSI can include one or more surface-emitting light sources such as surface-emitting light source 830 and surface-emitting light source 832. Data is sent by a first chiplet to a second chiplet. The sending is based on a first waveguide such as waveguide 860 within the plurality of waveguides. A transition is made between at least one low confinement region and at least one high confinement region. The transition includes the first waveguide. The second chiplet, such as chiplet 824, receives the data that was sent.

A data request can include sending data from a first chiplet to a second chiplet. The data request can be converted from electrical data, which can be serialized electrical data, to optical data, and reconverting the optical data to electrical data. In embodiments, the sending includes transmitting the data, by the first chiplet, to a first surface-emitting light source within one or more surface-emitting light sources. The electrical data can be converted to optical data using the surface-emitting light source such as surface-emitting light source 840. The surface-emitting light source can include a light source within a plurality of light sources. In embodiments, the PWSI includes one or more surface-emitting light sources. The surface-emitting light sources can be based on one or more varieties of light sources. In embodiments, the one or more surface-emitting light sources can include a vertical-cavity surface-emitting laser (VCSEL). Other types of light sources can also be used. In other embodiments, the one or more surface-emitting light sources can include a light emitting diode (LED).

In order to provide light from a surface-emitting light source to a waveguide, the light is conveyed to an optical coupler. Embodiments include conveying optical information, by the first surface-emitting light source 830, to a first optical coupler 850, wherein the first optical coupler couples the optical information to the first waveguide 860, and wherein the optical information is based on the data. The first coupler can be based on one or more coupling techniques. In embodiments, the first optical coupler can include a grating coupler. The grating coupler can diffract light at specific frequencies, thereby providing efficient transfer of light at a specific frequency into or out of a waveguide such as a waveguide within the PWSI. In embodiments, the first optical coupler comprises an off-axis diffractive lens. An off-axis diffractive lens can direct light at an angle with respect to the optical axis of the lens. In embodiments, the first optical coupler comprises a mirror. The mirror can be used to redirect light from the surface-emitting light source into the waveguide. In other embodiments, the first optical coupler comprises a bent waveguide. The bent waveguide can include a high containment region of a waveguide. The high containment waveguide can redirect the light while minimizing loss of light in the region of the bend of the waveguide.

The second chiplet 824 can receive the data that was sent. In embodiments, the receiving includes coupling the optical information, by a second optical coupler, from the first waveguide, to an optical receiver. The second optical coupler can be based on one or more receiving techniques. In embodiments, the second optical coupler can include a grating coupler. The second grating coupler can diffract light at specific frequencies to enable efficient transfer of light out of a waveguide within the PWSI. In other embodiments, the second optical coupler can includer a photodiode. The photodiode can convert the optical data to digital data. The data received at the optical coupler can be transferred. Embodiments include transferring, by the optical receiver, the data to the second chiplet. The data that is transferred can be transferred as optical data or transferred as digital data. The data can be received at the second chiplet by a receiver 870. If the receiver receives optical data, the receiver can convert the optical data to digital data. If the receiver receives digital data, the digital data can be used as received, converted from serial data to parallel data, and so on.

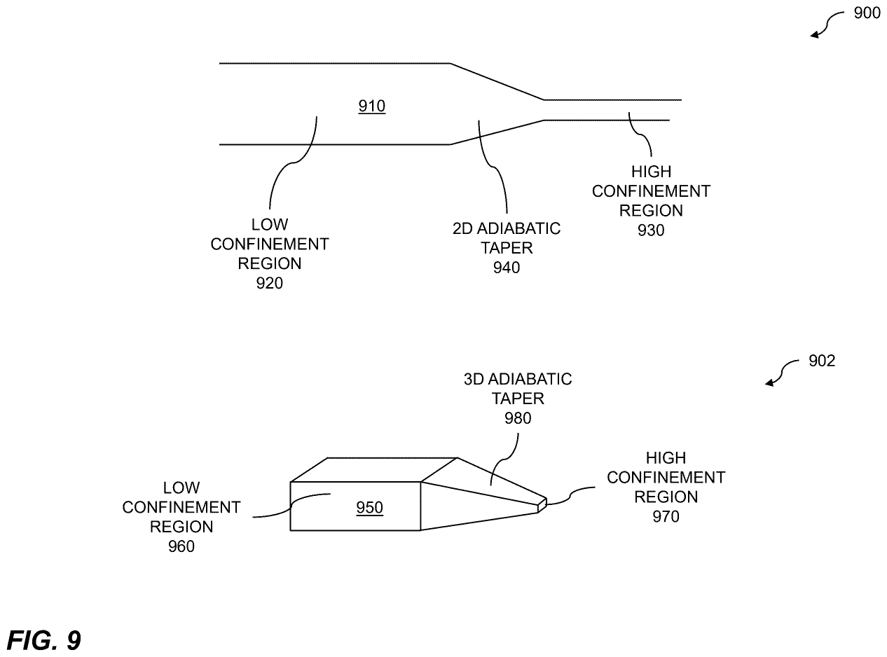

FIG. 9 is an example of waveguide tapering. Described previously and throughout, a photonic wafer-scale interposer (PWSI) includes a plurality of waveguides. Data can be sent between elements such as chiplets that are bonded to a front side of the PWSI. The waveguides provide a high-speed interconnection between a first chiplet and a second chiplet. In order to send data using a waveguide, digital data such as serial digital data is converted to optical data. The conversion can be accomplished using one or more surface-emitting light sources including a vertical-cavity surface-emitting laser (VCSEL), a light emitting diode (LED), and so on. Further, the optical data is coupled to the waveguide. The coupling can be accomplished using a grating coupler, an off-axis diffractive lens, a mirror, a bent waveguide, and the like. Light that is received at the other end of the waveguide is conveyed by a second optical coupler to a receiver associated with the second chiplet. The second optical coupler can include a grating coupler, a photodiode, a photo Darlington, etc. The data that is conveyed by the second optical coupler to the receiver is transferred, by the optical receiver, to the second chiplet. The data that is sent can be based on a data transfer request received from a node beyond the PWSI. The waveguide tapering can enable a transition within the waveguide between a low confinement region and a high confinement region within the waveguide. The waveguide tapering enables a photonic wafer-scale interposer.

The FIG. 900 shows a first, two-dimensional (2D) tapered waveguide 910. The first tapered waveguide can transition from a low confinement region 920 to a high confinement region 930. A low confinement region of a waveguide such as an optical waveguide is a region of the waveguide in which a signal such as a light signal is not tightly confined within the core of the waveguide. As a result, the light signal can extend beyond to the waveguide and into material surrounding the waveguide. A high confinement region of the waveguide, by contrast, can tightly confine a signal such as a light signal within the core of the waveguide, yielding minimal signal loss. The transition between the low confinement region of the waveguide and a high confinement region of the waveguide can be based on a taper. In embodiments, the tapering comprises adiabatic tapering 940. Adiabatic tapering can include gradually changing the cross-section of the waveguide. The gradual change of the waveguide cross-section can enable a smooth transition of a light signal from a first waveguide dimension to a second waveguide dimension with minimal signal loss. The tapering can enable a transition between different size and different shape regions of the waveguide. The adiabatic taper can accomplish high efficiency mode-connection power transfer between two regions of a waveguide.

The FIG. 902 shows a second, three-dimensional (3D) tapered waveguide 950. Similar to the 2D rendering, the second tapered waveguide can transition from a low confinement region 960 to a high confinement region 970. The transition between the low confinement region of the waveguide and a high confinement region of the waveguide can again be based on a taper. In embodiments, the tapering comprises adiabatic tapering 980. The adiabatic taper can be formed based on a variety of fabrication techniques. In embodiments, the tapering is based on three-dimensional (3D) lithography. The 3D lithography can form the adiabatic taper layer by layer. In embodiments, the tapering is based on three-dimensional (3D) lithography. The 3D lithography can enable fabrication of the tapered waveguide within a material such as polysilicon. In embodiments, the tapering is based on greyscale lithography. Grayscale lithography, which can include a microfabrication technique, can use gray values to create a 3D structure such as the tapered waveguide. The grayscale lithography can use light intensities of varying values to create 3D microstructures such as the 3D waveguide taper.

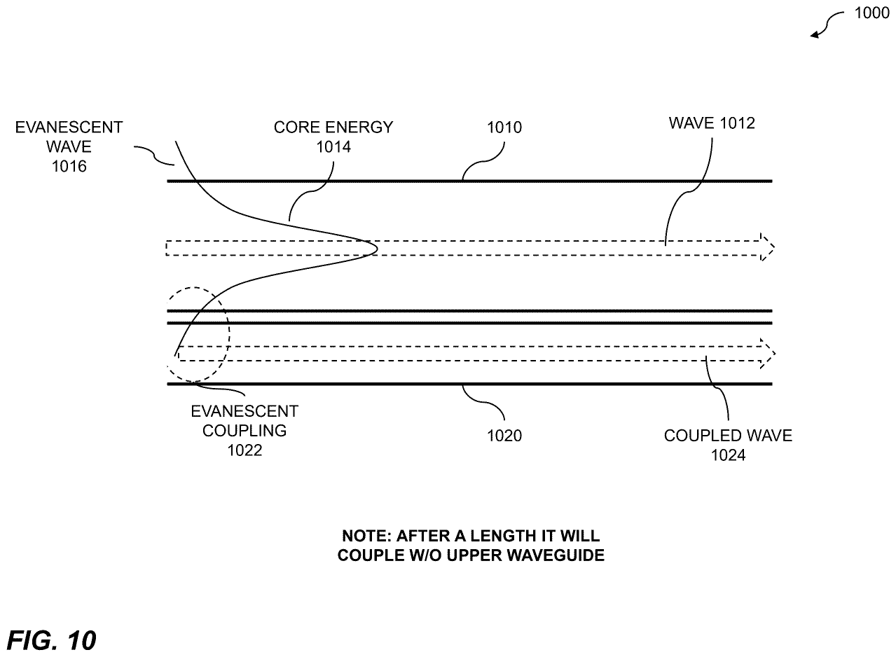

FIG. 10 is an example of evanescent coupling. Data can be sent between chiplets bonded to a photonic wafer-scale interposer (PWSI) using a waveguide. The data, which can include digital data, can be serialized and converted from digital data to optical data. The conversion of the digital data to the optical data can be accomplished using a surface-emitting light source such as a vertical-cavity surface-emitting laser (VCSEL), a light emitting diode (LED), and so on. The optical data can be sent between a first chiplet and a second chiplet using a waveguide within the PWSI. The optical data can be coupled to the waveguide using an optical coupler. The optical coupler can include a grating coupler, an off-axis diffractive lens, a mirror, a bent waveguide, and the like. The data that is sent can be received by the second chiplet. In embodiments, the receiving includes coupling the optical information, by a second optical coupler, from the first waveguide, to an optical receiver. The second optical coupler can include a grating coupler, a photo diode, a photo Darlington, etc. The optical receiver can transfer the data to the second chiplet. In embodiments, a transition is made between at least one low confinement region and at least one high confinement region. The transition includes the first waveguide. Thus, the optical signal within the low confinement region of the waveguide must be efficiently transferred to the high confinement region. In embodiments, the transitioning includes a second waveguide in the plurality of waveguides, wherein the transitioning is based on evanescent coupling. The evanescent coupling enables a photonic wafer-scale interposer with tapered waveguides.

The figure 1000 shows and example of evanescent coupling of an optical signal between a first waveguide and a second waveguide. The first waveguide and the second waveguide can include different cross-sections. In order to provide a transition between a low confinement and high confinement region, the first waveguide can include a low containment region of a waveguide, and the second waveguide can include a high containment region of a waveguide. A first waveguide is shown 1010. A wave such as an optical wave 1012 can travel along the first waveguide. An amount of energy can be associated with the optical wave. The energy associated with the optical wave can include a core energy 1014 portion. Since the first waveguide can be a low containment waveguide, a portion of the energy of the optical wave, the evanescent portion of the wave 1016 can extend beyond the core of the waveguide. If a second waveguide, such as waveguide 1020, is placed in close proximity to the first waveguide, then a portion of the evanescent wave can extend beyond the core of the first waveguide and into the core of the second waveguide, accomplishing evanescent coupling 1022. After the evanescent portion of the optical wave has extended into the second waveguide for a distance, the coupled wave 1024 continues to propagate in the second waveguide without evanescent coupling from the first waveguide.

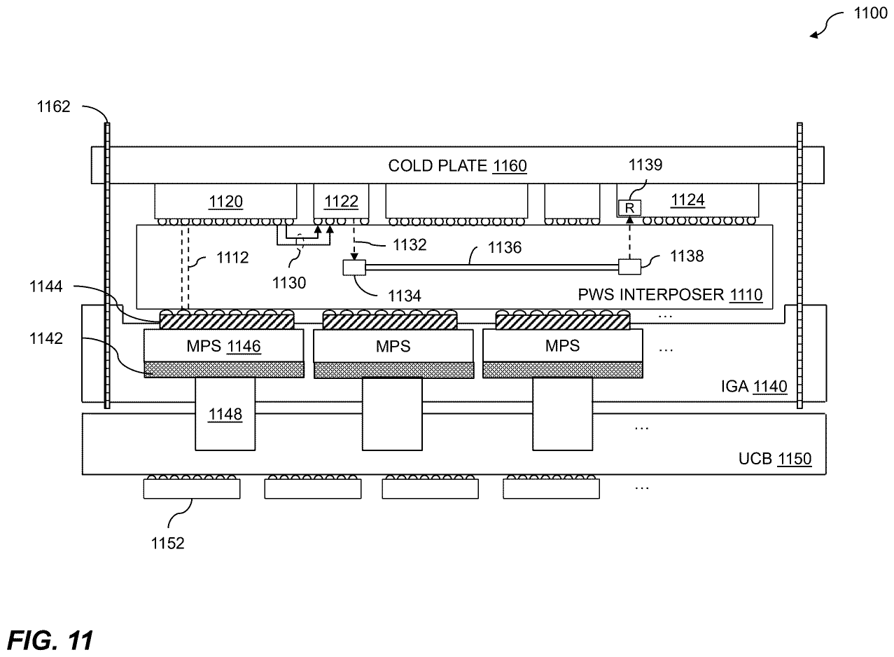

FIG. 11 is a cross-section of an apparatus for a photonic wafer-scale interposer with tapered waveguides. A variety of electronic and photonic elements can be attached, bonded, mounted, or otherwise coupled to the photonic wafer-scale interposer (PWSI). The variety of elements can include functional chips, AI accelerators, switching chiplets, and so on. Power such as DC power can be sent by a universal control board (UCB) to a plurality of elements including functional chips. The sending can be accomplished using a plurality of DC-to-DC converters, a plurality of modular power substrates (MPSs), and a plurality of through-silicon vias (TSVs). The plurality of functional chips, chiplets, etc. can be bonded to a front side of a photonic wafer-scale interposer (PWSI). The plurality of MPSs can be attached to a backside of the PWSI based on a plurality of conductive connecting materials. The conductive connecting materials can provide adhesion between the MPSs and the PWSI. The conductive connecting materials can further provide configurable or preconfigured conduction paths between the MPSs and the PWSI. The MPSs can be mechanically connected to the UCB based on a plurality of high-power sockets. The UCB can further include a plurality of DC-to-DC power converters. The attaching can further include compressing by an isometric grid array (IGA). The IGA compresses the conductive connecting materials. The IGA can include a compression plate. The IGA can be stiffened based on a plurality of reinforcements. The stiffening can accomplish one or more goals associated with the apparatus. The stiffening can enable planar compression of the elastomer sheet. In embodiments, the planar compression is based on the one or more spring-loaded fasteners. The planar compression can be based on one or more clamps. The planar compression can enable consistent adhesion of the MPSs to a back side of the PWSI. The planar compression can further enable reliable coupling of conduction paths through the conductive connecting material to contacts, pads, etc. associated with the MPSs and the PWSI.

The plurality of through-silicon vias (TSVs) associated with the PWSI can be used to provide connections between a front side of the PWSI and a back side of the PWSI. The PWSI can be used to achieve wafer-scale integration (WSI), based on a photonic wafer-scale interposer with tapered waveguides. The PWSI can be used to mount various elements such as electrical elements, optical elements, electro-optical elements, and so on. The PWSI can further provide interconnections among the mounted elements, and tapered waveguides within the PWSI, to transfer optical data. An apparatus for sending data is disclosed comprising: a photonic wafer-scale interposer (PWSI), wherein the PWSI includes a plurality of waveguides, wherein a front side of the PWSI is bonded to at least two chiplets, and wherein the at least two chiplets include a first chiplet and a second chiplet; and a first waveguide within the plurality of waveguides, wherein the first waveguide includes a transition between at least one low confinement region and at least one high confinement region, and wherein the first waveguide couples the first chiplet and the second chiplet.

The apparatus 1100 includes a photonic wafer-scale interposer (PWSI) 1110, wherein the PWSI includes a plurality of waveguides, wherein a front side of the PWSI is bonded to at least two chiplets, and wherein the at least two chiplets include a first chiplet and a second chiplet.

The at least two chiplets can include one or more processor chips, multi-core processor chips, graphics processor chips, systems-on-a-chip (SoCs), memory chips, ASICSs, artificial intelligence (AI) or machine learning (ML) accelerators, a vertical-cavity surface-emitting laser (VCSEL), and so on. The chiplets can include an integrated circuit designed for a flip-chip application. A chip design for a flip-chip application can include a chip for which connections to the chip are accomplished at the top layer of the chip. The connections can include positive and negative DC power connections, data connections, control connections, and so on. The various chip connections can include pads on the top layer of the chips. The functional chips can include a chip that can accomplish a processing function such as a deep learning function, a network switching function, and so on.

The PWSI includes a plurality of through-silicon vias (TSVs) such as TSV 1112. The PWSI can include inorganic materials or organic materials. In a usage example, the PWSI can include a silicon interposer. Micro-bumps discussed above can be used to mount the one or more chiplets, such as chiplets 1120 and 1124, to the front side of the PWSI. The PWSI can include one or more light sources. In embodiments, the apparatus 1100 includes a first surface-emitting light source, wherein the first chiplet transmits data to the first surface-emitting light source 1122. Microbumps can also be used to attach one or more surface-emitting light sources. The surface-emitting light source can be used to transfer data between the first chiplet and the second chiplet. The surface-emitting light source can be used to convert digital data such as serial digital data to optical data. The optical data can include serial optical data.

Communications between the chiplets and the surface-emitting light sources can be accomplished within metal layers of the interposer. The chiplet 1120 can be coupled to surface-emitting light source 1122 via interposer wire 1130. Use of wiring within the PWSI reduces latency and parasitics such as resistance, capacitance, and inductance, and enables improvement of signal integrity and/or bandwidth, etc. Optical data from the surface-emitting light source can be coupled to a waveguide within the PWSI. The optical data can be conveyed 1132 to an optical coupler. In embodiments, the apparatus 1100 includes a first optical coupler 1134, wherein the first surface-emitting light source conveys optical information to the first optical coupler, wherein the first optical coupler couples the optical information to the first waveguide 1136, and wherein the optical information is based on the data. Discussed previously, the optical coupler can include a grating coupler, an off-axis diffractive lens, a mirror, a bent waveguide, and the like. The waveguide can include a tapered waveguide. The waveguide can be tapered using a variety of techniques. Also discussed previously, the tapering the waveguide can be accomplished using adiabatic tapering, three-dimensional (3D) lithography, grayscale lithography, and so on.

In embodiments, the apparatus 1100 includes a second optical coupler 1138, wherein the second optical coupler couples the optical information from the first waveguide. The second optical coupler can be based on a grating coupler, a photodiode, a photo Darlington, and the like. An optical receiver 1139 can be coupled to the second optical coupler. In embodiments, the apparatus 1100 includes an optical receiver, wherein the second optical coupler couples the optical information to the optical receiver, and wherein the optical receiver transfers the data to the second chiplet 1124. Thus, digital data can be sent from the first chiplet to the second chiplet by converting the digital data to optical data, coupling the optical data to a waveguide, and receiving the optical data at a receiver that converts the optical data to digital data, and transfers the digital data to the second chiplet. The sending data optically between chiplets can significantly reduce data transfer latency and can improve data integrity. Thus, the PWSI can enable extremely high bandwidth buses and control signals between chiplets mounted to the PWSI. The PWSI can include one or more optical waveguides. The optical waveguides can enable chiplet-to-chiplet communications via one or more wavelengths of light. The optical waveguides can comprise the buses and control signals between chiplets. The photonic interposer can also be used to attach additional boards, modules, components, and so on. The further attachments can be located on the opposite side of the PWSI from the mounted chiplets and surface-emitting light sources.

The apparatus 1100 can include an isometric grid array (IGA) 1140. The IGA can enable support of and stiffening of the photonic wafer-scale interposer. Recall that the PWSI can be ground and polished to a thinness that is able to support the TSVs. As a result, the PWSI can deflect under the weight of the components that can be bonded, attached, and coupled to it. The IGA can support and planarize the PWSI, thereby preventing the PWSI from fracturing. The IGA can include a plurality of reinforcement structures 1142, wherein each reinforcement structure in the plurality of reinforcement structures enables planar compression of each conductive connecting material within a plurality of conductive connecting materials. An example conductive connecting material is shown 1144. Each reinforcement structure 1142 in the plurality of reinforcement structures can stiffen each modular power substrate (MPS), such as MPS 1146, in a plurality of MPSs. Each MPS within the plurality of MPSs can include a connector. For the apparatus 1100, a connector can comprise a socket 1148. The socket can include a socket on a unified control board (UCB) (described below). The socket can comprise a high-power socket, a high voltage socket, and so on. The mechanical connection can include one or more plugs, pins, terminals, contacts, etc. from the UCB which can be inserted into the socket. In a usage example, the mechanical connection can be based on a high voltage socket, wherein the high voltage socket transfers power from the UCB to the plurality of MPSs. The high voltage socket can be used to provide a first DC voltage. The first DC voltage can be provided by a DC-to-DC converter. The first DC voltage can be converted to a second DC voltage by one or more DC-to-DC converters. The mechanical connection can accommodate a maximum lateral displacement of the UCB due to thermal expansion during operation. In a usage example, the mechanical connection can include a compliant connector. The lateral displacement can result from thermal expansion of the PWSI, the UCB, and/or the MPS during operation.

The apparatus 1100 can include a unified circuit board (UCB) 1150, wherein the UCB is mechanically connected to the plurality of MPSs, wherein the UCB includes a plurality of DC-to-DC converters, wherein the UCB sends DC power to the at least two chiplets bonded to the PWSI. The sending can be based on the plurality of MPSs and the plurality of TSVs. The MPS discussed previously can be mechanically connected to a unified control board (UCB). An MPS can include a connector, where the connector can be used to mechanically connect the MPS to the UCB. For the apparatus 1100, the connector can comprise the socket 1148 on the UCB. The socket can comprise a high-power socket, a high voltage socket, and so on. The mechanical connection can include one or more plugs, pins, terminals, contacts, etc. from the UCB which can be inserted into the socket. In a usage example, the mechanical connection can be based on a high voltage socket, wherein the high voltage socket transfers power from the UCB to the plurality of MPSs. The high voltage socket can be used to provide a first DC voltage that can be converted to a second DC voltage by one or more DC-to-DC converters. The mechanical connection can accommodate a maximum lateral displacement of the UCB due to thermal expansion during operation. In a usage example, the mechanical connection can include a compliant connector. The lateral displacement can result from thermal expansion of the PWSI, the UCB, and/or the MPS during operation.

The UCB can include a plurality of DC-to-DC power converters 1152. As described above, each DC-to-DC power converter in the plurality of DC-to-DC power converters can include a mechanical connection to a respective MPS in the plurality of MPSs. The mechanical connection between each DC-to-DC converter and a respective MPS can enable power transfer, control, and so on. The mechanical connections between the plurality of DC-to-DC converters and the plurality of MPSs can remain reliable when the DC-to-DC converters and the MPSs are operating. The mechanical connection can accommodate a maximum lateral displacement of the UCB due to thermal expansion during operation. The handling a maximum lateral displacement is critical to maintaining reliable mechanical connections between and among components, the PWSI, one or more UCBs, one or more MPSs, and so on.

The UCB 1150 can include a digital controller chip (not shown). The DC-to-DC converters can be controlled by a control chip associated with the UCB. The digital controller chip can control power delivery to the plurality of functional chips. The controlling power delivery can include enabling or disabling power transfer, controlling an input voltage to an output voltage from a DC-to-DC converter, and the like. A usage example can include matching each DC-to-DC power converter within the plurality of DC-to-DC power converters included on the UCB to one or more respective MPSs in the plurality of MPSs. DC power from a DC-to-DC converter can be sent to an MPS via an interconnect on the UCB. DC power can be fed to the DC-to-DC converters. Recall that an MPS can include a connector that can accommodate lateral displacement of the UCB due to thermal expansion during operation. The connector can accomplish other functions. In a usage example, the connector can include one or more power control signals from the digital controller chip to the plurality of MPSs. The control signals can enable and disable elements such as controller chips and DC-to-DC converters, can provide instructions to controller chips, etc. In a further usage example, the connector can carry at least a portion of DC power from the plurality of MPSs to the plurality of functional chips. As explained above and throughout, the PWSI and the UCB can expand at different rates due to different CTEs. Thus, the MPSs that are attached to the UCB can also move, which can cause connections associated with the elastomer sheets between the PWSI and the MPSs to become unreliable. To mitigate this movement due to expansion, as explained previously, the MPS can be designed modularly, effectively isolating movement between MPSs. In addition, the socket, which can be a high-power socket, a high voltage socket, etc., can comprise a compliant connector.

For the apparatus 1100, the plurality of MPSs can be attached to a back side of the PWSI by a plurality of conductive connecting materials 1144. The apparatus can include a number of different conductive connecting materials. The plurality of conductive connecting materials can comprise a plurality of elastomer sheets, a plurality of anisotropic conductive films (ACFs), a plurality of isotropic conductive adhesives (ICAs), and so on. An MPS can be coupled to one or more elements associated with the PWSI. In embodiments, each MPS in the plurality of MPSs is coupled to one or more chiplets and/or surface-emitting light sources within the at least two chiplets and light sources. In embodiments, each MPS within the plurality of MPSs is based on a form factor mirroring one or more corresponding functional chips within the plurality of functional chips on the front side of the PWSI. The form factor of the MPS can be associated with or dependent on components mounted to the wafer interposer. In a usage example, the plurality of MPSs can be based on a form factor mirroring the corresponding chiplet. The form factor of the MPS can have a 1:1 relationship to the one or more corresponding chiplets or can include other shape factors. The MPSs can be based on a variety of materials. In a usage example, one or more MPSs within the plurality of MPSs comprise an inorganic substrate. An inorganic substrate can include a silicon substrate, a glass substrate, and so on. In another usage example, one or more MPSs within the plurality of MPSs comprise an organic substrate. The organic substrates can include substrates such as printed circuit boards. Recall that the chiplets and surface emitting light sources are mounted to the front or top side of the PWSI. In embodiments, the plurality of MPSs is attached to a back side of the PWSI. Connections between the wafer interposer and the MPS can be accomplished using the conductive connecting materials 1144. The plurality of conductive connecting materials attaches, which can include adhering, the MPSs to the PWSI. The plurality of conductive connecting materials further provides conduction paths between pads or contacts associated with the MPSs and corresponding pads or contacts associated with the PWSI.

An MPS 1146 can include a plurality of step-down power modules and/or DC-to-DC power converters. The DC-to-DC converters on an MPS can be placed across the MPS. The DC-to-DC power converters on the MPSs can accomplish altering of a DC voltage. The altering the DC voltage can result in a second DC voltage. In a usage example, the power can be altered, wherein altering, by the plurality of MPSs, is accomplished by the DC power that was sent, and wherein the altering is based on a second voltage conversion. The second voltage conversion can include a second DC-to-DC voltage conversion. In embodiments, the second voltage conversion results in a voltage less than a threshold. The threshold can include a voltage appropriate to a voltage required by a functional chip. In embodiments, the threshold can include 1 volt.

The apparatus 1100 can include a cold plate 1160. The cold plate can be attached to one or more chiplets, surface-emitting light sources, etc. The cold plate can be mounted to an isometric grid array (IGA) (described above). The cold plate can be used to extract a portion of heat generated by chiplets, light sources, and other elements as the functional chiplets etc. operate. Recall that prodigious amounts of heat can be generated by chips and other electronic elements as they are operating. This point can be particularly relevant to high-performance chips. The mounting of the cold plate to a grid such as the IGA can be accomplished using clips, screws, bolts, clamps, and so on. For the apparatus, the cold plate can be mounted to the IGA using clamps such as clamp 1162.

In embodiments, the planar compression is based on the one or more spring-loaded fasteners. In other embodiments, the planar compression is based on one or more clamps. The clamps can provide more compression force than the spring-loaded fasteners. Both spring-loaded fasteners and clamps can be used. The MPS can be stiffened for a variety of purposes. Recall that MPSs are attached to the back side of the PWSI based on a plurality of conductive connecting materials. When the conductive connecting materials comprise certain materials, such as elastomer sheets, a sufficient force can be applied substantially equally across the plurality of MPSs to form a reliable electrical coupling between the MPSs and the PWSI. When an adhesive material is used, the IGA can be used to apply sufficient force to enable adhesion. In embodiments, the IGA comprises a compression plate. In other embodiments, the IGA maintains a coplanarity of the PWSI. Recall that a cold plate is mounted to the IGA. In embodiments, the mounting is based on one or more clamps 1162. Any other fasteners, such as a screw, spring loaded clip, and so on, can be used. The spring-loaded fasteners can squeeze the PWSI between the cold plate and the IGA. The pressure on the PWSI can be exerted by the IGA through the MPSs after they have been inserted into the reinforcement structure. This can enable planar compression on the PWSI. In embodiments, the planar compression is based on the one or more spring-loaded fasteners.

The coplanarity of each MPS can enable adhesion and/or connection by the conductive connecting materials without causing the PWSI to deflect, crack, fracture, and so on. Each reinforcement structure can be formed using a variety of techniques. Usage examples can include depositing, on each MPS within the plurality of MPSs, the reinforcement structure. The reinforcement structure can be deposited using a fabrication technique such as chemical vapor deposition (CVD). Other embodiments include gluing, to each MPS within the plurality of MPSs, the reinforcement structure. The gluing can be accomplished using adhesives such as an epoxy, cyanoacrylate, and so on.

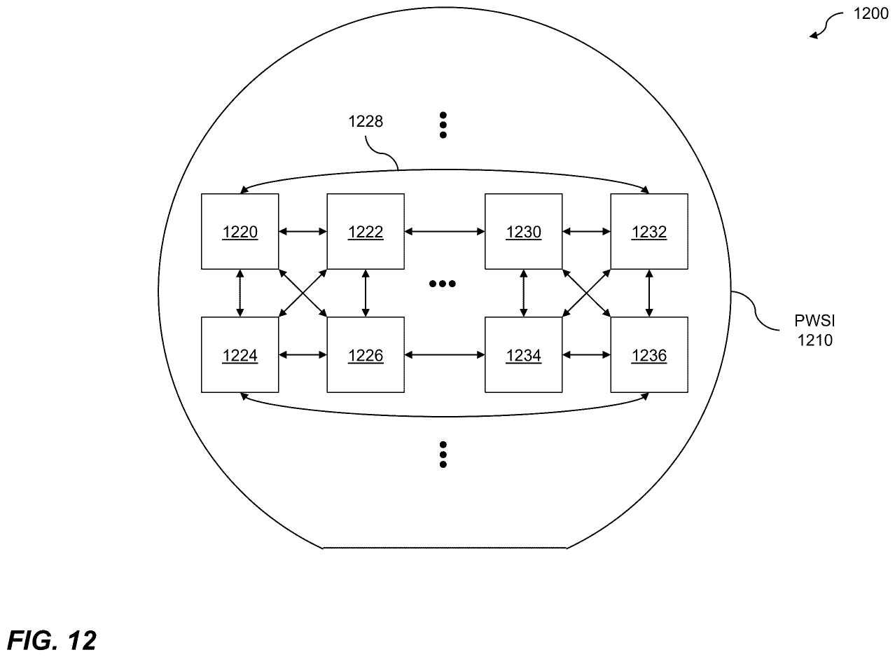

FIG. 12 is an example of a HyperX™ network topology implemented with a photonic wafer-scale interposer (PWSI). Discussed previously and throughout, a photonic wafer-scale interposer with tapered waveguides can be used to accomplish high-speed data transfers between two or more chiplets bonded to the PWSI. A first chiplet can receive a data transfer request to send data to a second chiplet. The data transfer request can be received by a node external to the PWSI. The data transfer request can be directed to a second node external to the PWSI. The PWSI can comprise an AI accelerator, network switch, or another compute function. In the case of a network switch, the PWSI can implement a HyperX™ topology between switching chips. The HyperX™ network topology offers significant improvements in comparison to other network technologies such as ring network topologies, star network topologies, mesh network topologies, and so on. The improvements by the HyperX™ network topology include scalability, ease of installation, redundancy, and fault tolerance, among other improvements. A HyperX™ network topology implemented with a photonic wafer-scale interposer (PWSI) is enabled by tapered waveguides within the PWSI. A photonic wafer-scale interposer (PWSI) is accessed. The PWSI includes a plurality of waveguides. A front side of the PWSI is bonded to at least two chiplets. The at least two chiplets are coupled. The coupling is based on one or more waveguides in the plurality of waveguides. Data is sent by a first chiplet within the at least two chiplets to a second chiplet within the at least two chiplets. The sending is based on a first waveguide within the plurality of waveguides. A transition is made between at least one low confinement region and at least one high confinement region. The transition includes the first waveguide. The data that was sent is received by the second chiplet.

A plurality of parameters associated with a HyperX™ network can be adjusted to benefit switching characteristics of the HyperX™ network. A HyperX™ network can enable high-radix switches. A high-radix switch, such as a high-radix switching chiplet, can enable a substantial number of connections per chiplet. Enabling the connections supports high-throughput data transfer. The HyperX™ network can scale efficiently. Efficient scaling of a network can enable processing of high data bandwidth applications such as machine learning applications. The HyperX™ network can enable adaptive routing. The adaptive routing can vary routing across the network as amounts of data traffic across the network vary over time. The HyperX™ network can enable a “low diameter” network. A low diameter network can enable data transfer between nodes of the HyperX™ network, such as data transfer between chiplets such as switching chiplets, with a low number of hops between nodes. A low number of hops (e.g., intermediate switching chiplets) between a source chiplet and a destination chiplet reduces network latency.

The figure shows an example HyperX™ network 1200. The HyperX™ network is shown implemented on a photonic wafer-scale interposer (PWSI) 1210. The PWSI can be based on one or more types of wafers such as a silicon (Si) wafer, a glass wafer, and so on. Recall that a front side of the PWSI can be bonded to at least two chiplets such as switching chiplets. The chiplets, which can include modular integrated circuits or chips, can include circuits designed for high-speed switching applications. The switching can be based on optical switching, electro-optical switching, etc. In the figure, two quads of elements are shown. The elements can include networking elements such as switches, routers, smart hubs, and so on. In embodiments, the elements comprise switching chiplets. The first quad of elements includes elements 1220, 1222, 1224, and 1226. The second quad of elements includes elements 1230, 1232, 1234, and 1236. While two quads of elements are shown, other groupings of switching chiplets can be implemented. Also, more than two groupings of the switching chiplets can be bonded to the PWSI. Interconnection is provided between and among the switching chiplets. The interconnections between the switching chiplets can be provided by the plurality of waveguides included in the PWSI. The waveguides can be coupled to each chiplet by one or more surface-emitting light sources as described above. Further interconnection for connections such as power, control, and so on can be provided between the switching chiplets using metal (wire) interconnect. In addition to interconnections provided between “nearest neighbor” switching chiplets, interconnections can be provided between clusters of chiplets. An example interconnection 1228 is shown between switching chiplet 1220 and switching chiplet 1232. These latter interconnections minimize the “diameter” of the HyperX network. The HyperX network implemented with a PWSI as shown can enable efficient use of multicore optical fiber interconnect which, in some non-PWSI implementations, must be connected to multiple switches within the network.

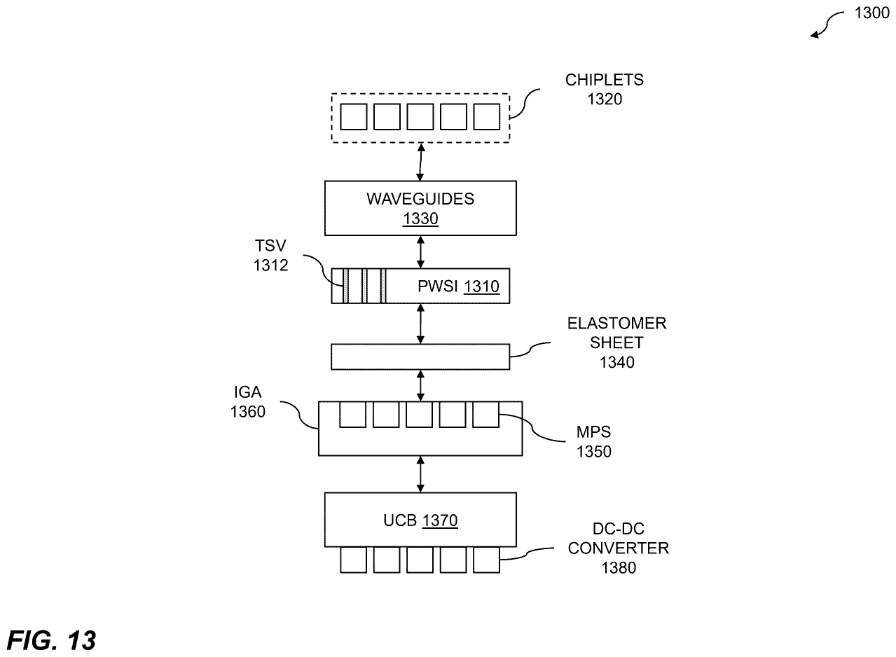

FIG. 13 is a system diagram for a photonic wafer-scale interposer (PWSI) with tapered waveguides. A plurality of waveguides including the tapered waveguides can be formed within the PWSI. The waveguides can enable high-speed communication with chiplets bonded to a front side of the PWSI. Data that is transferred between the chips can include digital data such as serial electronic data. The electronic data can be converted at a first chiplet to optical data in order to be transferred to a second chiplet using a waveguide. The optical data can be received at the second chiplet and can be converted to electronic data. The PWSI can be attached to an isometric grid array (IGA). The IGA includes a plurality of reinforcement structures. Each reinforcement structure in the plurality of reinforcement structures can enable planar compression of one or more elastomer sheets. The elastomer sheets can enable the attachment of modular power substrates (MPSs) (described below) to the PWSI. The IGA can accomplish stiffening of a photonic wafer-scale interposer (PWSI). Power can be provided to the PWSI by a unified control board. Recall that the PWSI can be bonded to at least two chiplets. The chiplets can include AI accelerator chiplets, processors, ASICS, switching chiplets, surface-emitting light sources, and so on. Other chips such as functional chips can also be bonded to the PWSI. The functional chips can include processors, multiprocessors, machine learning (ML) processors, graphics processors, memories, switches, and so on. The chiplets can be bonded to a front side of the PWSI. The chiplets can be in communication with elements such as modular power substrates (MPSs) that can be attached to a back side of the PWSI. The communication between the chiplets and the MPSs can be accomplished using through-silicon vias (TSVs). To enable the fabrication of the TSVs and to improve the reliability of the TSVs, the PWSI can be ground, polished, and so on to reduce the thickness of the PWSI. The resulting thin PWSI can be delicate and therefore susceptible to fracturing. Attaching of the MPSs can be based on a plurality of conductive connecting materials. The attaching can include compressing, by an isometric grid array (IGA), each conductive connecting material within the plurality of conductive connecting materials. The attaching couples each MPS within the plurality of MPSs to one or more chiplets within the two or more chiplets. The attaching can further couple each MPS to one or more functional chips.

Disclosed is a system for sending data comprising: a photonic wafer-scale interposer (PWSI), wherein the PWSI includes a plurality of waveguides, wherein a front side of the PWSI is bonded to at least two chiplets, and wherein the at least two chiplets include a first chiplet and a second chiplet; and a first waveguide within the plurality of waveguides, wherein the first waveguide includes a transition between at least one low confinement region and at least one high confinement region; and wherein the first waveguide couples the first chiplet and the second chiplet, wherein the system is configured to: send data from the first chiplet to the second chiplet.

The system 1300 includes a photonic wafer-scale interposer (PWSI) 1310, wherein the PWSI includes a plurality of waveguides, and wherein a front side of the PWSI is bonded to at least two chiplets, and wherein the at least two chiplets include a first chiplet and a second chiplet. The PWSI can further include a plurality of through-silicon vias (TSVs) 1312. The PWSI can comprise an inorganic wafer such as a silicon wafer. The inorganic wafer can include a material within which waveguides such as tapered waveguides can be fabricated. The at least two chiplets 1320 can include switching chiplets, surface-emitting light sources, general purpose chiplets, ASICs, AI accelerators, etc. The chiplets can further include optical light sources including surface-emitting light sources. The surface-emitting light sources can include vertical-cavity surface-emitting lasers (VCSELs), light emitting diodes (LEDs), and so on. The chiplets, surface-emitting light sources, and other elements can create prodigious heat during operation. The heat can be due to current provided to the chiplets such as active current, overcurrent, leakage current, and so on. The heat can result from IR drops associated with interconnect, active devices, leakage current, etc. within the chiplets. The chiplets can be bonded to the PWSI via micro-bumps, controlled collapse chip connections (C4s), and so on. The PWSI includes a plurality of through-silicon vias (TSVs) 1312. A TSV can include an electrical connection that completely passes through a wafer such as a silicon wafer or a die. The plurality of TSVs is oriented vertically in order to enable connections between the front side of the wafer and the back side of the wafer.

The system 1300 includes a plurality of waveguides 1330. Each waveguide within the plurality of waveguides can enable sending data such as optical data between a first chiplet and a second chiplet. In order to provide reliable sending of data such as optical data via the waveguide, the waveguide can transition between and among regions. In embodiments, the system 1300 includes a first waveguide within the plurality of waveguides, wherein the first waveguide includes a transition between at least one low confinement region and at least one high confinement region, and wherein the first waveguide couples the first chiplet and the second chiplet.

In embodiments, a transition is made between at least one low confinement region and at least one high confinement region. The transition includes the first waveguide. A low confinement region of a waveguide can include a region in which light within the waveguide is not highly confined. As a result, light can be lost from the low confinement region, coupled to an adjacent waveguide, and so on. A high confinement region of a waveguide can lose less light within the region of the waveguide compared to the low containment region. In embodiments, the transitioning includes tapering the first waveguide. Various techniques can be used to accomplish the tapering of the waveguide. In embodiments, the tapering comprises adiabatic tapering. A waveguide taper based on an adiabatic taper can change size and shape of an optical beam mode. The adiabatic taper can accomplish high efficiency mode-connection power transfer between two regions of a waveguide. In embodiments, the tapering is based on three-dimensional (3D) lithography. The 3D lithography can enable fabrication of the tapered waveguide within a material such as polysilicon. In embodiments, the tapering is based on greyscale lithography. Grayscale lithography, which can include a microfabrication technique, can use gray values to create a 3D structure such as the tapered waveguide. In other embodiments, the transitioning includes a second waveguide within the plurality of waveguides, wherein the transitioning is based on evanescent coupling. According to Maxwell's Equations, an evanescent wave can extend somewhat beyond a waveguide in which a wave is traveling. Thus, a small portion of a light wave can be coupled into a nearby waveguide when the waveguides are in proximity.

The system 1300 can include a plurality of conductive connecting materials such as elastomer sheets 1340. The plurality of conductive connecting materials enables attaching a plurality of modular power substrates (MPSs). In embodiments, the plurality of conductive connecting materials comprises a plurality of elastomer sheets. The plurality of elastomer sheets can include a variety of materials, configurations, and so on. In some embodiments, a single elastomer sheet can be used. An elastomer sheet can comprise conductive particles, which can be a filament, such as brass, gold, etc., embedded in a sheet of silicone rubber or another suitable material. The filament can be at regular intervals within the elastomer sheet. In the system 1300, the conductive particles are shown to be distributed throughout the conductive sheet in an “unprogrammed” state. That is, as shown, the conductive paths have yet to be “activated.” However, the conductive elements, or filaments, can be “pre-programmed” to be embedded on a pitch. The pitch can be designed to match a connector array, such as a ball grid array (BGA) of a modular power substrate (MPS). Thus, the elastomer sheet may not need any activation in order to form one or more conductive paths. The elastomer sheet can be held in place with a compression force. An adhesive backing can be added to the elastomer sheet. Thus, the elastomer sheet can accomplish adhesion of the one or more chips to the one or more PCBs. The elastomer sheet can provide conduction paths between the one or more chips and the one or more PCBs.

The system 1300 can include a plurality of modular power substrates (MPSs) 1350, wherein the plurality of MPSs is attached to a back side of the PWSI by a plurality of elastomer sheets 1340. Described previously and throughout, the MPSs can include one or more DC-to-DC converters, a high voltage socket, a high voltage connector, and so on. In embodiments, each MPS within the plurality of MPSs is based on a form factor mirroring one or more corresponding functional chips within the plurality of functional chips on the front side of the PWSI. The system 1300 can include an isometric grid array (IGA) 1360, wherein the IGA includes a plurality of reinforcement structures, wherein each reinforcement structure in the plurality of reinforcement structures enables planar compression of each elastomer sheet within the plurality of elastomer sheets. The IGA and each reinforcement structure within the plurality of reinforcement structures accomplishes stiffening of each MPS in the plurality of MPSs. In embodiments, the IGA maintains a coplanarity of the PWSI. Maintaining coplanarity of the PWSI reduces the risk of the PWSI fracturing or cracking under pressure applied by the IGA.

The system 1300 can include a unified circuit board (UCB) 1370, wherein the UCB is mechanically connected to the plurality of MPSs, wherein the UCB includes a plurality of DC-to-DC converters 1380. The mechanical connection of the UCB to the plurality of MPSs can be accomplished using a variety of connection techniques, where the connection techniques can be accomplished using locking connectors, non-locking connectors, screws, bolts, clamps, and so on. The connectors can include rigid connectors, high-power connectors, high voltage connectors, and the like. The mechanical connection can be based on a high-power socket (which can be a high voltage socket). The modularity of the MPSs can allow for movement between the UCB and the PWSI. Movement, such as a linear displacement, can occur due to differences in coefficients of thermal expansion (CTE). The USB can include one or more control circuits. The control circuits can be used to generate control signals to one or more functional chips, enable transfers of data, control DC-to-DC converters, and the like. The UCB includes a plurality of DC-to-DC power converters 1380. The DC-to-DC converters can convert DC power from a high DC voltage range, such as 48 volts to 54 volts, to a lower DC voltage range, such as 12 volts to 13.5 volts. The DC-to-DC converters can be mounted on the unified control board (UCB) 1370. The UCB can provide controls such as control signals, and power such as DC power, to the DC-to-DC converters. The UCB can comprise a single control board. The single control board can include an organic control board or an inorganic control board. The UCB can comprise multiple control boards and/or circuits. The UCB can include a printed circuit board (PCB). The PCB can include a ceramic board, a glass board, and the like. In some embodiments, the PCB comprises aluminum nitride. Aluminum nitride can have a similar CTE to silicon, reducing the lateral displacement between the PWSI and the UCB during operation. The system 1300, when provided power, is configured to: send DC power to the at least two chiplets bonded to the PWSI, wherein the sending is based on the plurality of DC-to-DC converters, the plurality of MPSs, and the plurality of TSVs. The sending can include the first voltage conversion and the second voltage conversion as described above.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for sending data comprising:
accessing a photonic wafer-scale interposer (PWSI), wherein the PWSI includes a plurality of waveguides, and wherein a front side of the PWSI is bonded to at least two chiplets;
coupling the at least two chiplets, wherein the coupling is based on one or more waveguides in the plurality of waveguides;
sending data, by a first chiplet within the at least two chiplets, to a second chiplet within the at least two chiplets, wherein the sending is based on a first waveguide within the one or more waveguides;
transitioning between at least one low confinement region and at least one high confinement region, wherein the transitioning includes the first waveguide; and
receiving, by the second chiplet, the data that was sent.

2. The method of claim 1 wherein the transitioning includes tapering the first waveguide.

3. The method of claim 2 wherein the tapering comprises adiabatic tapering.

4. The method of claim 2 wherein the tapering is based on three-dimensional (3D) lithography.

5. The method of claim 2 wherein the tapering is based on greyscale lithography.

6. The method of claim 1 wherein the transitioning includes a second waveguide in the plurality of waveguides, wherein the transitioning is based on evanescent coupling.

7. The method of claim 1 wherein the transitioning enables a bend in the first waveguide.

8. The method of claim 1 wherein the first waveguide is based on reticle stitching.

9. The method of claim 1 wherein the PWSI includes one or more surface-emitting light sources.

10. The method of claim 9 wherein the one or more surface-emitting light sources comprise a vertical-cavity surface-emitting laser (VCSEL).

11. The method of claim 9 wherein the one or more surface-emitting light sources comprise a light emitting diode (LED).

12. The method of claim 9 wherein the sending includes transmitting the data, by the first chiplet, to a first surface-emitting light source within one or more surface-emitting light sources.

13. The method of claim 12 further comprising conveying optical information, by the first surface-emitting light source, to a first optical coupler, wherein the first optical coupler couples the optical information to the first waveguide, and wherein the optical information is based on the data.

14. The method of claim 13 wherein the first optical coupler comprises a grating coupler.

15. The method of claim 13 wherein the first optical coupler comprises an off-axis diffractive lens.

16. The method of claim 13 wherein the first optical coupler comprises a mirror.

17. The method of claim 13 wherein the first optical coupler comprises a bent waveguide.

18. The method of claim 13 wherein the receiving includes coupling the optical information, by a second optical coupler, from the first waveguide, to an optical receiver.

19. The method of claim 18 wherein the second optical coupler comprises a grating coupler.

20. The method of claim 18 wherein the second optical coupler comprises a photodiode.

21. The method of claim 18 further comprising transferring, by the optical receiver, the data to the second chiplet.

22. The method of claim 9 wherein the one or more surface-emitting light sources are coupled to the PWSI by micro-transfer printing.

23. An apparatus for sending data comprising:
a photonic wafer-scale interposer (PWSI), wherein the PWSI includes a plurality of waveguides, wherein a front side of the PWSI is bonded to at least two chiplets, and wherein the at least two chiplets include a first chiplet and a second chiplet; and
a first waveguide within the plurality of waveguides, wherein the first waveguide includes a transition between at least one low confinement region and at least one high confinement region, and wherein the first waveguide couples the first chiplet and the second chiplet.

24. The apparatus of claim 23 further comprising a first surface-emitting light source, wherein the first chiplet transmits data to the first surface-emitting light source.

25. The apparatus of claim 24 further comprising a first optical coupler, wherein the first surface-emitting light source conveys optical information to the first optical coupler, wherein the first optical coupler couples the optical information to the first waveguide, and wherein the optical information is based on the data.

26. The apparatus of claim 25 further comprising a second optical coupler, wherein the second optical coupler couples the optical information from the first waveguide.

27. The apparatus of claim 26 further comprising an optical receiver, wherein the second optical coupler couples the optical information to the optical receiver, and wherein the optical receiver transfers the data to the second chiplet.

28. A system for sending data comprising:
a photonic wafer-scale interposer (PWSI), wherein the PWSI includes a plurality of waveguides, wherein a front side of the PWSI is bonded to at least two chiplets, and wherein the at least two chiplets include a first chiplet and a second chiplet; and
a first waveguide within the plurality of waveguides, wherein the first waveguide includes a transition between at least one low confinement region and at least one high confinement region; and wherein the first waveguide couples the first chiplet and the second chiplet, wherein the system is configured to:
send data from the first chiplet to the second chiplet.
